(19) United States
(12) Patent Application Publication
(10) Pub. No.: US 2026/0223448 A1
(43) Pub. Date: Jul. 30, 2026

(54) SEMICONDUCTOR DEVICE WITH ISOLATION WALLS AND METHODS OF FORMING THE SAME

(71) Applicant: TAIWAN SEMICONDUCTOR MANUFACTURING COMPANY, LTD., Hsinchu (TW)

(72) Inventors: Guan-Lin CHEN, Hsinchu (TW); Shang-Wen CHANG, Hsinchu (TW); Kuo-Cheng CHIANG, Hsinchu (TW); Shi Ning JU, Hsinchu (TW); Chih-Hao WANG, Hsinchu (TW)

(21) Appl. No.: 19/216,857

(22) Filed: May 23, 2025

Related U.S. Application Data
(60) Provisional application No. 63/749,038, filed on Jan. 24, 2025.

(51) Int. Cl. H10D 84/85; H10D 84/01

(52) U.S. Cl. CPC H10D 84/852; H10D 84/0167; H10D 84/017; H10D 84/0186; H10D 84/0188

(57) ABSTRACT

Embodiments of the present disclosure is a semiconductor device that, includes a first channel region and a second channel region disposed over a semiconductor substrate; a gate structure having a longitudinal axis in a first direction and extending across the first channel and second channel regions, and the gate structure includes an interfacial layer, a gate dielectric layer, and a gate electrode; a first epitaxial feature and a second epitaxial feature interposing the first channel region and the gate structure in a second direction perpendicular to the first direction; and an isolation structure extending between the first and second channel regions. The isolation structure has a first sidewall facing the first channel region, and a portion of the first sidewall between a top of the first channel region and a bottom of the first channel region is covered by the gate dielectric layer and the interfacial layer.

### CROSS-REFERENCE TO RELATED APPLICATIONS

This application claims priority to U.S. Provisional Application Ser. No. 63/749,038 filed on Jan. 24, 2025, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device, in accordance with some embodiments.

FIGS. 7A-20D are plan views and cross-sectional views of various stages of manufacturing a semiconductor device, in accordance with some embodiments.

FIGS. 21-21C are a plan view and a cross-sectional view of an intermediate stage of manufacturing a semiconductor device, in accordance with some embodiments.

FIGS. 22A-28D are plan views and cross-sectional views of an intermediate stage of manufacturing a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiment of the present disclosure provide a semiconductor device and methods of manufacturing thereof. The semiconductor device includes a gate structure crossing one or more channel regions and source/drain epitaxial features interposing the channel regions. The semiconductor device also includes an isolation wall extend through the gate structure and the source/drain features. Adjacent source/drain epitaxial features may be separated by the isolation wall, and therefore the problem of unwanted bridge between adjacent epitaxial features can be resolved. In addition, the formation of the isolation walls is compatible with ordinary cut metal process and thus can provide more flexibility on the design of circuits.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, FinFETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

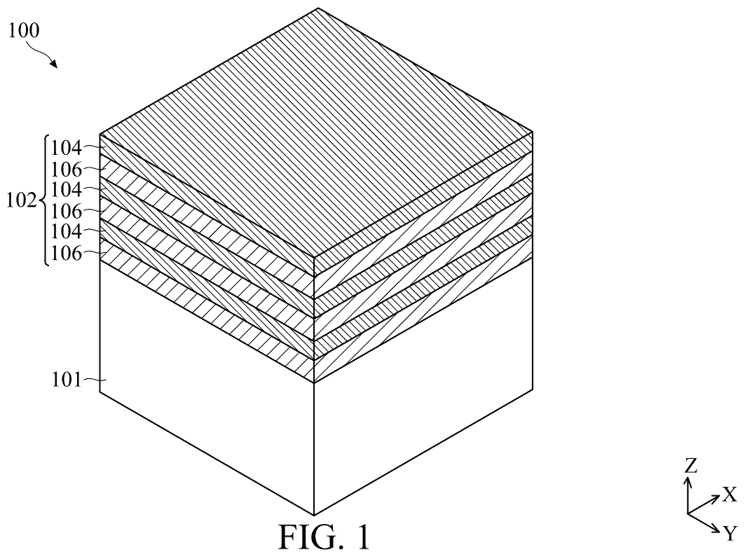

FIGS. 1-28D show exemplary processes for manufacturing semiconductor devices according to embodiments of the present disclosure. It is understood that additional operations can be provided before, during, and after processes shown by FIGS. 1-28D, and some of the operations described below can be replaced or eliminated, for additional embodiments of the method. The order of the operations/processes is not limiting and may be interchangeable.

FIGS. 1-20D illustrates exemplary processes for manufacturing a semiconductor device 100, in accordance with some embodiments. FIGS. 1-6 are perspective views of intermediate stages in manufacturing a semiconductor device 100. The semiconductor device 100 also includes a multilayer stack 102 formed over the substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer. The substrate 101 may include various regions that have been doped with impurities (e.g., dopants having p-type or n-type conductivity) in the substrate 101. Depending on circuit design, the substrate 101 may include p-type doped wells for an n-type field effect transistors (NFET) n-type doped wells for a p-type field effect transistors (PFET).

The multilayer stack 102 includes alternating semiconductor layers made of different materials to facilitate the formation of nanostructure channels in a multi-gate device, such as nanostructure channel FETs. In some embodiments, the multilayer stack 102 includes first semiconductor layers 104 and second semiconductor layers 106 that are alternately stacked over the substrate 101. For example, the multilayer stack 102 is illustrated as including three layers of first semiconductor layers 104 and three layers of second semiconductor layers 106 for illustrative purposes. It is appreciated that any number of the first and second semiconductor layers 104, 106 can be included in the multilayer stack 102. In some embodiments, the first semiconductor layers 104 are formed of a first semiconductor material, and the second semiconductor layers 106 are formed of a second semiconductor material different from the first semiconductor material. The second semiconductor material may have a different etch selectively and/or oxidation rate than the first semiconductor material. In some embodiments, either the first semiconductor material or the second semiconductor material is or includes a material such as SiGe, SiC, GeAs, GaP, InP, InAs, InSb, GaAsP, AlInAs, AlGaAs, InGaAs, GaInP, GaInAsP, combinations thereof, or the like. In some embodiments, the first semiconductor material is formed of Si, and the second semiconductor material is formed of SiGe, or vice versa.

Each first semiconductor layer 104 may have a thickness in a range between about 5 nm and about 30 nm. Each second semiconductor layer 106 may have a thickness that is equal, less, or greater than the thickness of the first semiconductor layer 104. In some embodiments, each second semiconductor layer 106 has a thickness in a range between about 2 nm and about 50 nm. The first and second semiconductor layers 104, 106 are formed by any suitable deposition process, such as epitaxy deposition. By way of example, the epitaxial deposition of the multilayer stack 102 may be performed by vapor-phase epitaxy (VPE), molecular beam epitaxy (MBE), chemical vapor deposition (CVD), metalorganic chemical vapor deposition (MOCVD) process, atomic layer deposition (ALD), the like, and/or other suitable epitaxial growth processes.

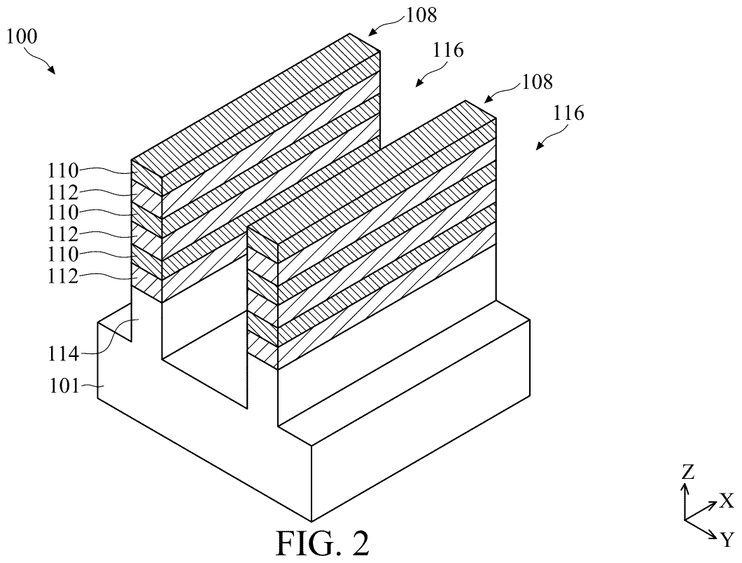

In FIG. 2, the multilayer stack 102 and the substrate 101 are patterned by one or more etch processes to form semiconductor strips 108, in accordance with some embodiments. Each semiconductor strip 108 may include first nanostructures 110 patterned from the first semiconductor layers 104 and second nanostructures 112 patterned from the second semiconductor layers 106. The substrate 101 may include a plurality of fins 114 after the etch processes. The semiconductor strips 108 are disposed over the fins 114, respectively. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section.

The semiconductor strips 108 may be formed by patterning a hard mask layer (not shown) formed on the multilayer stack 102 using multi-patterning operations that include lithography and etch processes. The etch process can include dry etching such as reactive ion etching (RIE) or neutral beam etching (NBE), wet etching, and/or other suitable processes. The lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etch process forms trenches 116 in unprotected regions through the hard mask layer, through the multilayer stack 102, and into the substrate 101, thereby leaving the semiconductor strips 108 and the fins 114. The trenches 116 extend along the X direction. In some embodiments, the semiconductor strips 108 and the fins 114 have a longitudinal axis along the X direction.

The semiconductor device 100 may include a plurality of transistor structures. The first nanostructures 110 or portions thereof may form nanostructure channel(s) of the transistor structures in later fabrication stages, while the second nanostructures 112 may act as sacrificial layers in later fabrication stages for allowing the nanostructure channel(s) to be surrounded by gate structures. The transistor structures having the nanostructure channel(s) may be referred to as nanostructure transistors, nanosheet transistors, nanowire transistors, gate-all-around (GAA) transistors, multi-bridge channel (MBC) transistors, or any transistors having gate electrodes surrounding channels.

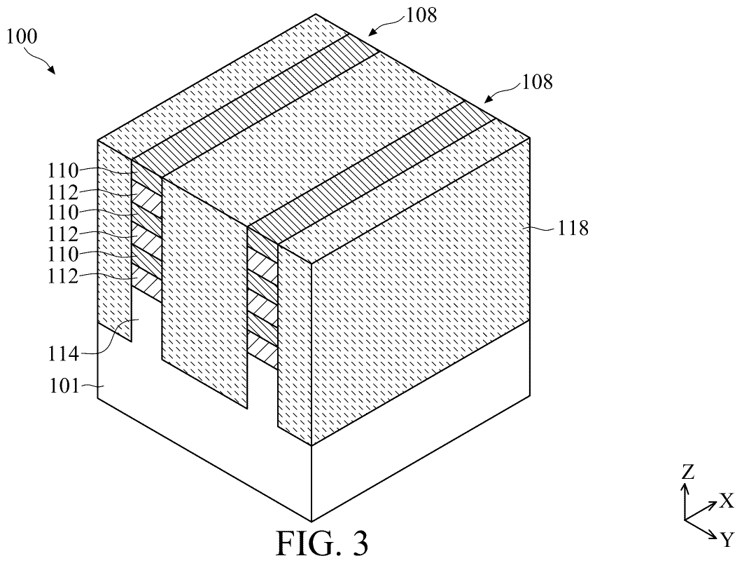

In FIG. 3, after the semiconductor strips 108 are formed, an insulating material 118 is formed over the substrate 101. The insulating material 118 fills the trenches 116 between neighboring semiconductor strips 108 until the semiconductor strips 108 are embedded in the insulating material 118. Then, a planarization operation, such as a chemical mechanical polishing (CMP) method and/or an etch-back method, is performed such that the top of the semiconductor strips 108 is exposed. The insulating material 118 may be made of silicon oxide, silicon nitride, silicon oxynitride (SiON), SiOCN, SiCN, fluorine-doped silicate glass (FSG), a low-K dielectric material (dielectric constant less than about 3.5), or any suitable dielectric material. The insulating material 118 may be formed by any suitable method, such as flowable CVD (FCVD), low-pressure chemical vapor deposition (LPCVD), or plasma-enhanced CVD (PECVD).

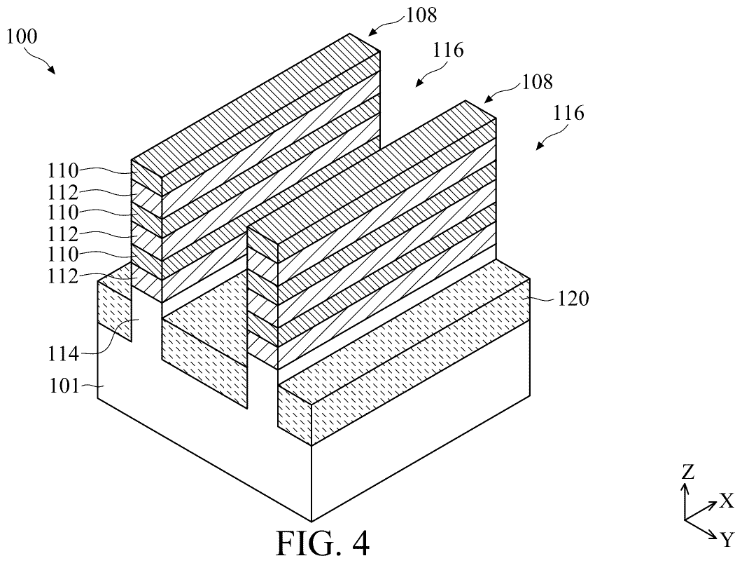

In FIG. 4, the insulating material 118 is recessed to form shallow trench isolation (STI) regions 120. The recess of the insulating material 118 exposes portions of the semiconductor strips 108 and the substrate 101. The recess of the insulating material 118 reveals the trenches 116 between the neighboring semiconductor strips 108. The STI regions 120 may be formed using a suitable process, such as a dry etch process, a wet etch process, or a combination thereof. Top surfaces of the STI regions 120 may be level with or below top surfaces of the fins 114 and in contact with the fins 114.

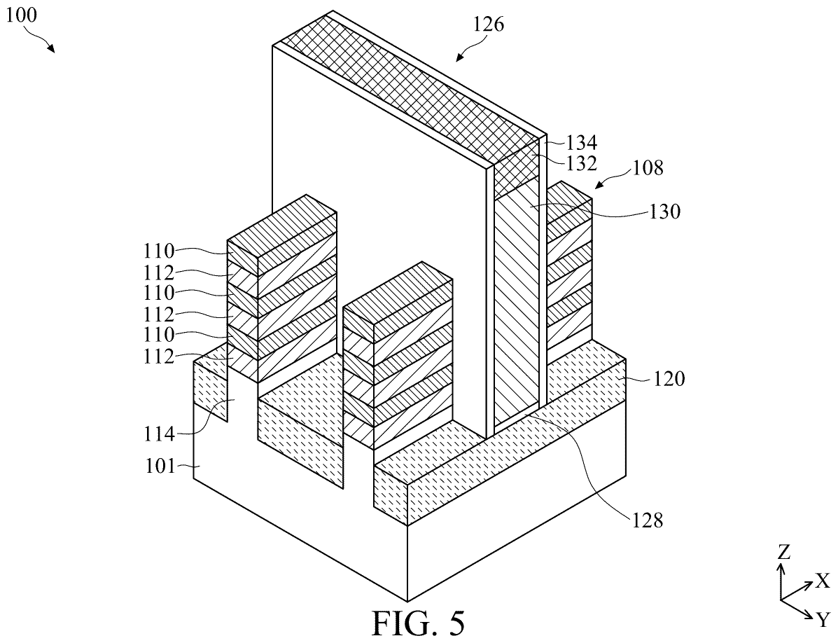

In FIG. 5, one or more dummy gate structures 126 (only one is shown) are formed over the semiconductor device 100. The dummy gate structures 126 are formed over a portion of the semiconductor strips 108. Each dummy gate structure 126 may include a dummy gate dielectric 128, a dummy gate electrode 130, and an optional hard mask 132. The dummy gate dielectric 128, the dummy gate electrode 130, and the hard mask 132 may be formed by sequentially depositing blanket layers of the dummy gate dielectric 128, the dummy gate electrode 130, and the hard mask 132, and then patterning those layers into the dummy gate structures 126. The dummy gate structure 126 may have a longitudinal direction (e.g., the Y-direction in FIG. 5) substantially perpendicular to the longitudinal directions of the semiconductor strips 108 (e.g., the X-direction in FIG. 5). The dummy gate structure 126 may land on the STI regions 120 and cross over a single one or a plurality of the semiconductor strips 108.

The dummy gate dielectric 128 may include one or more layers of dielectric material, such as a deposited oxide-based material (e.g., silicon oxide) or a material oxidized from the substrate 101. The dummy gate electrode 130 may include silicon such as polycrystalline silicon or amorphous silicon. The hard mask 132 may include one or more dielectric layers. For example, the hard mask 132 may be a combination of an oxide layer and a nitride layer.

Gate spacers 134 are then formed on sidewalls of the dummy gate structure 126. The gate spacers 134 may be formed by conformally depositing one or more layers for the gate spacers 134 and anisotropically etching (e.g., RIE) the one or more layers. Dielectric materials such as silicon nitride (SiN), silicon oxide (SiO), silicon carbide (SiC), silicon oxide (SiOₓ), silicon carbo-nitride (SiCN), silicon oxynitride (SiON), silicon oxy-carbo-nitride (SiOCN), combinations thereof, or the like, may be used for the gate spacers 134.

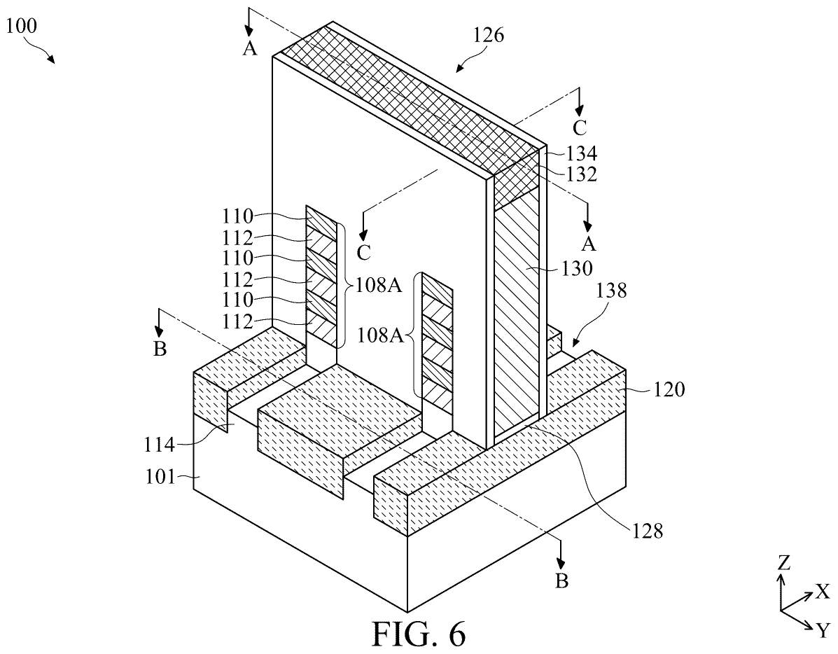

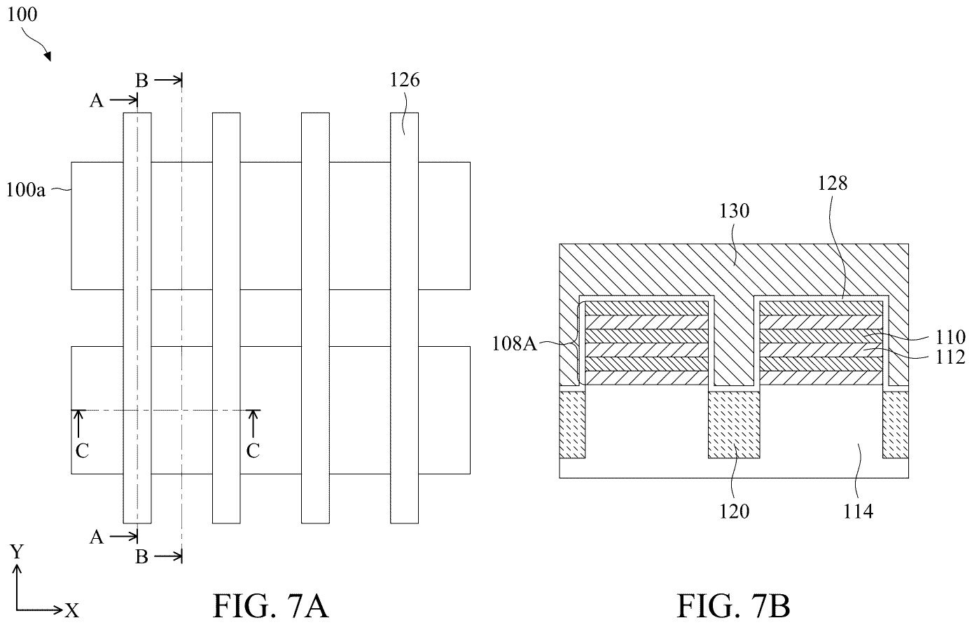

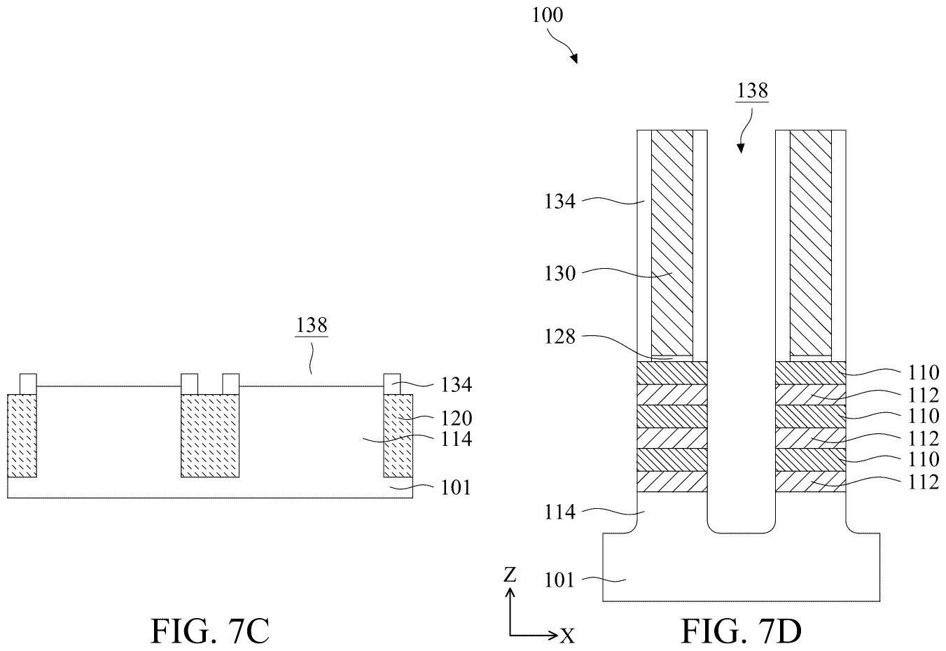

In FIG. 6, first openings 138 are formed in the semiconductor strips 108, the fins 114, and the substrate 101, in accordance with some embodiments. The first openings 138 may be formed by removing at least portions of the semiconductor strips 108 and the substrate 101 that are not protected by the gate spacers 134 and the dummy gate structure 126. The remaining portions of the semiconductor strips 108 under the dummy gate structures 126 may form nanostructure stacks 108A. Each of the nanostructure stack 108A may be interposed by first openings 138. As such, the first openings 138 may be formed between neighboring dummy gate structures 126 in the X-direction as illustrated in FIG. 6 (or the cross-sectional view illustrated in FIG. 7D). The first openings 138 may be recessed to below the top surfaces of the STI regions 120, although the first openings also can be recessed to level with or above the top surfaces of the STI regions 120. The first openings 138 may be formed by an etch process, either isotropic or anisotropic etch process, and the etch process may be selective with respect to one or more crystalline planes of the substrate 101. The etch process may be a dry etch, such as a RIE, NBE, or the like, or a wet etch. The etchant from the etch process may include fluorocarbons or chlorocarbons.

The process of manufacturing the semiconductor device 100 continue to proceed in FIGS. 7A-20D and will be illustrated in plan views and cross-sectional views. FIG. 7A is a plan view of the semiconductor device 100, and FIGS. 7B, 7C, and 7D are cross-sectional views of the semiconductor device 100 taken in directions along cross-section A-A, cross-section B-B of FIG. 6, and cross-section C-C of FIG. 6, respectively. Throughout the description (including the semiconductor devices 100, 200, and 300), the figures with figure numbers including “A” are plan views of semiconductor devices; the figures with figure numbers including “B” are referenced from the cross-section A-A as illustrated in FIG. 6 or FIG. 7A; the figures with figure numbers including “C” are referenced from the cross-section B-B as illustrated in FIG. 6 or FIG. 7A; and the figures with figure numbers including “D” are referenced from the cross-section C-C as illustrated in FIG. 6 or FIG. 7A. For clarity purposes, source/drain features, dielectric (or insulating) layers or insulating regions may not be illustrated in these plan view of the semiconductor devices. Although FIG. 6 illustrates one dummy gate structure 126 and two semiconductor strips 108, it is appreciated that the semiconductor device 100 may include more dummy gate structures 126 and more semiconductor strips 108. In FIG. 7A, the active regions 100a may be surrounded by the STI regions 120 (not shown in FIG. 7A). As illustrated in FIGS. 7B and 7C, the dummy gate structures 126 having a longitude axis extending the Y-direction are provided, and each dummy gate structure 126 may extend cross one or multiple nanostructure stacks 108A in one or more active regions 100a. In FIG. 7D, the first openings 138 extend through the nanostructure stacks 108A and into the substrate 101, in accordance with some embodiments. The first openings 138 may be interposed between opposing gate spacers 134 and expose the fins 114/substrate 101.

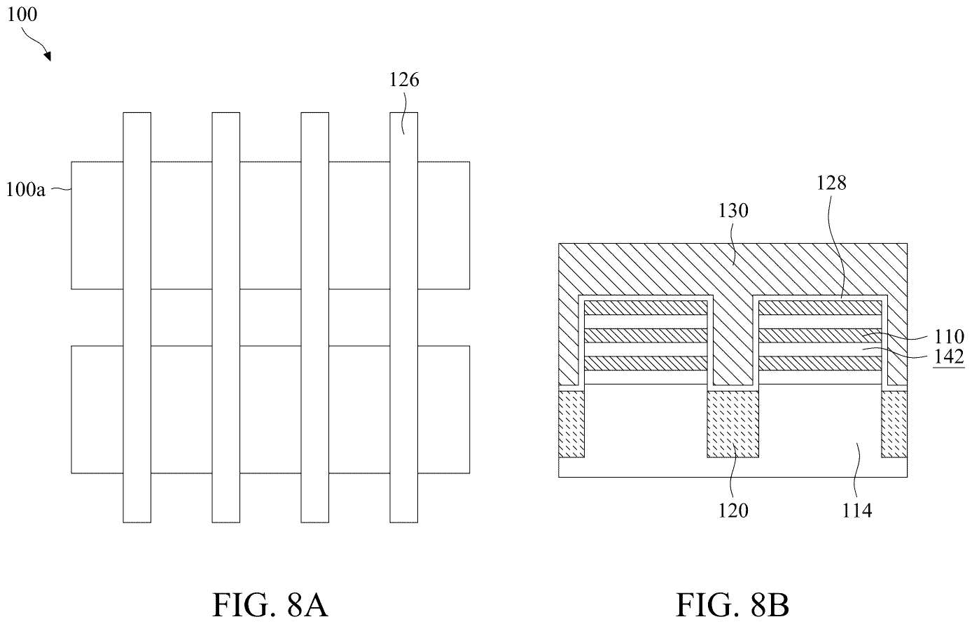

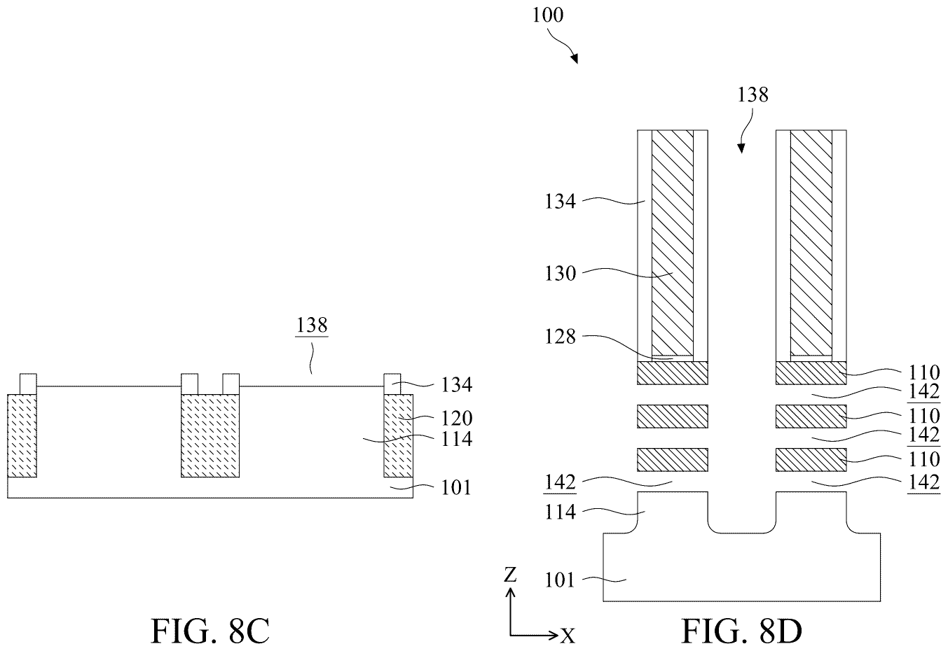

Next, referring to FIGS. 8A-8D, the second nanostructures 112 are etched to form second openings 142, in accordance with some embodiments. That is, the second openings 142 may be space that was occupied by the second nanostructures 112, including the space between the vertically adjacent first nanostructures 110 and between the bottommost first nanostructure 110 and the fins 114/substrate 101. While using etchants selective to etch the second semiconductor material of the second nanostructures 112, the first nanostructures 110 and the substrate 101 remain relatively unetched. In an embodiment that the second semiconductor material includes, e.g., SiGe, an etch process using a hydroxide etchant, such as tetramethylammonium hydroxide (TMAH), ammonium hydroxide (NH₄OH), or the like, is used.

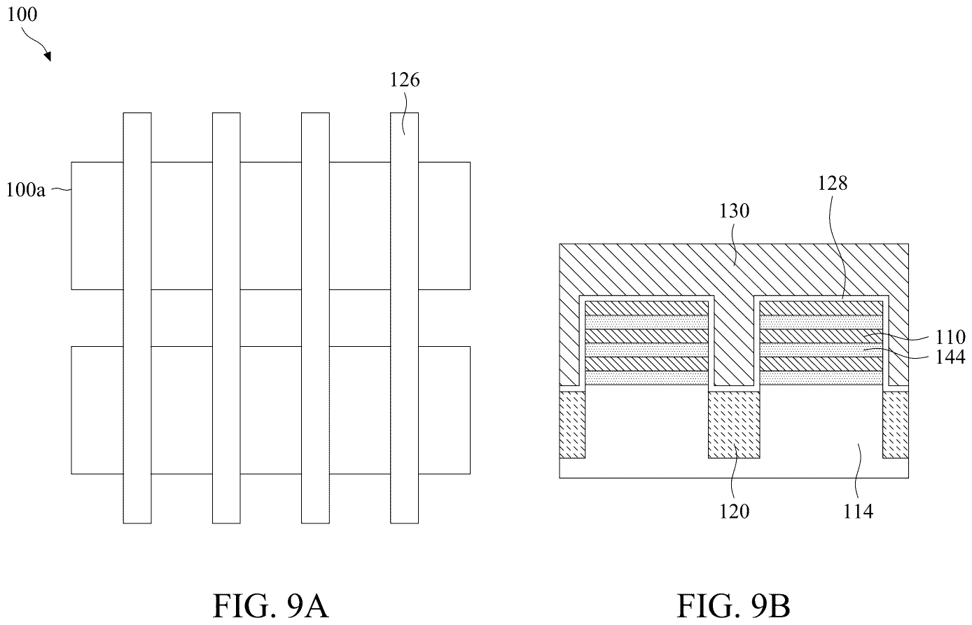

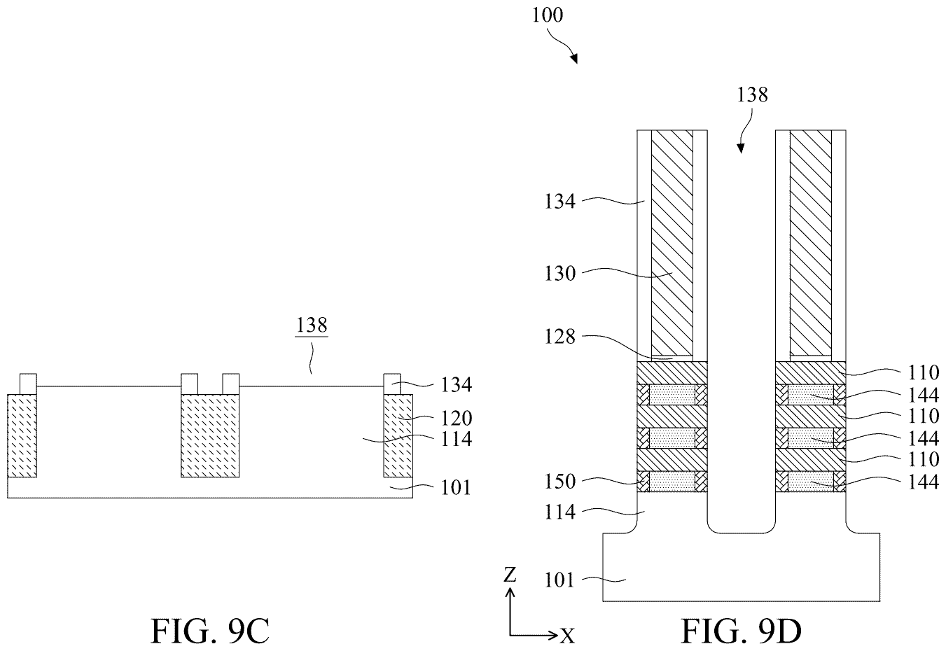

In FIGS. 9A-9D, insulating nanostructures 144 are formed in the second openings 142, in accordance with some embodiments. The insulating nanostructures 144 may include an oxide-containing material, such as silicon oxide, silicon oxynitride, fluorine-doped silicate glass (FSG), a low-K dielectric material, or any suitable dielectric material. In some embodiments, the insulating nanostructures 144 includes a material similar to those of the STI regions 120. The formation of the insulating nanostructures 144 may include depositing an insulating layer in the first openings 138 and the second openings 142, such as by FCVD, ALD, PECVD, LPCVD, combinations thereof, or the like. The insulating layer may be a conformal layer in the first openings 138. In addition, given the size differences between the first openings 138 and the second openings 142, the insulating layer may substantially or completely fill the second openings 142. Afterwards, an etch process is performed to remove the insulating layer in the first openings 138 and laterally recess the insulating layer in the second openings 142. The etch process may use etchants selective to etch the insulating layer, and the first nanostructures 110 and the substrate 101 may remain relatively unetched. In some embodiments, the etch process or another etch process laterally recesses the insulating layer from the first openings 138. Inner spacers 150 may be formed in the lateral recesses created by the etch process and on the sidewalls of the insulating nanostructures 144. The inner spacers 150 may include an insulating material, such as SiO, SiOC, SiC, SiN, SiON, or a combination thereof. The inner spacers 150 may act as isolation features between subsequently formed gate structure and epitaxial structures.

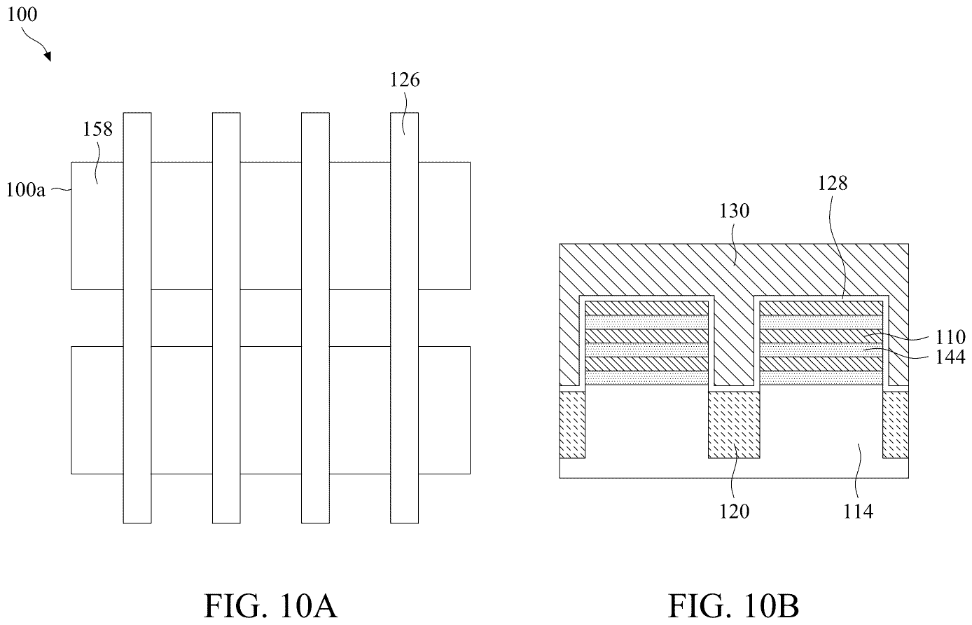

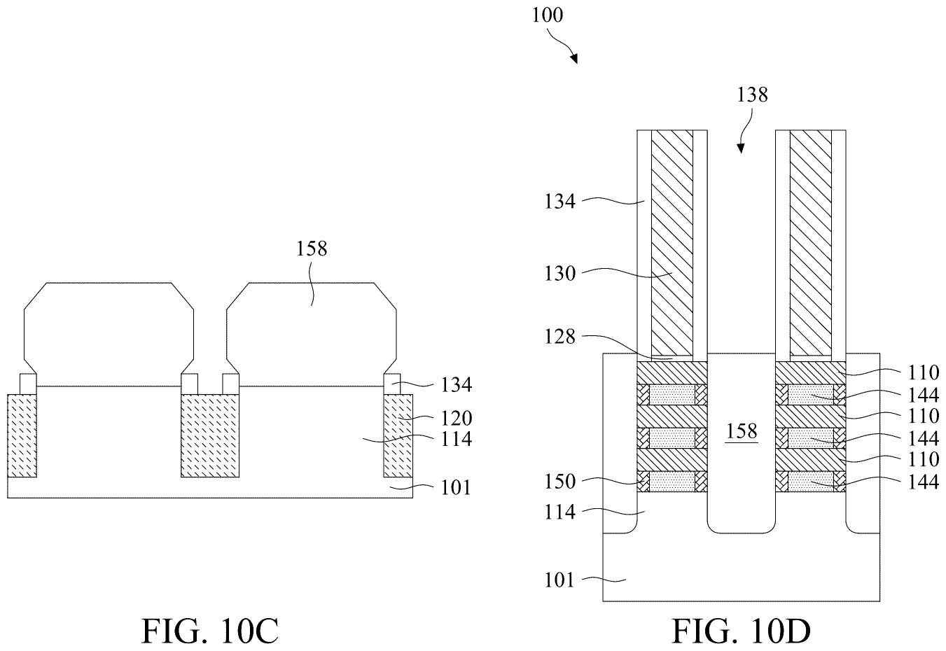

In FIGS. 10A-10D, epitaxial structures 158 are formed in the first openings 138, in accordance with some embodiments. The epitaxial structures 158 may be source/drain regions of the semiconductor device 100 and can also be referred to as epitaxial source/drain structures 158. In this disclosure, a source region and a drain region are interchangeably used, and the structures thereof are substantially the same. Furthermore, source/drain region(s) may refer to a source or a drain, individually or collectively dependent upon the context. The epitaxial structures 158 may be formed by an epitaxial growth method using such as, CVD, ALD, MBE, combinations therefore, or the like. In some embodiments, the impurities may be in situ doped when epitaxially depositing the epitaxial structures 158. The epitaxial structures 158 may have an impurity concentration of between about 1×10¹⁹ atoms/cm³ and about 1×10²¹ atoms/cm³. The epitaxial structures 158 may exert stress on the first nanostructures 110, thereby improving device performance. The epitaxial structures 158 may have facets. As shown in FIG. 10C, one epitaxial structure 158 includes at least two upper slanted surfaces opposing each other and two lower slanted surfaces opposing each other, in accordance with some embodiments.

In some embodiments, the epitaxial structures 158 include more than one epitaxial semiconductor layers. For example, each of the epitaxial structures 158 may comprise a first semiconductor material layer, a second semiconductor material layer, and a third semiconductor material layer. Any number of semiconductor material layers may be used for the epitaxial structures 158. Each of the first semiconductor material layer, the second semiconductor material layer, and the third semiconductor material layer may be formed of same or different semiconductor materials and may be doped to different dopant concentrations. In an embodiment, the first semiconductor material layer, the second semiconductor material layer, and the third semiconductor material layer include a same semiconductor material with different concentrations. For example, in an embodiment that the semiconductor material is SiGe, the Ge concentrations in the first semiconductor material layer, the second semiconductor material layer, and the third semiconductor material layer are different. In some embodiments, the first semiconductor material layer may have a dopant concentration less than the second semiconductor material layer and greater than the third semiconductor material layer. In embodiments in which the epitaxial structures 158 comprise three semiconductor material layers, the first semiconductor material layer may be deposited, the second semiconductor material layer may be deposited over the first semiconductor material layer, and the third semiconductor material layer may be deposited over the second semiconductor material layer.

The epitaxial structures 158 may be an n-type epitaxial structure for n-type FETs (e.g., NMOS) and a p-type epitaxial structure for p-type FETs (e.g., PMOS). In some embodiments, the n-type epitaxial structure for the n-type FETs include Si, SiP, SiC, SiCP, and SiAs, and the p-type epitaxial structure for the p-type FETs include Si, SiGe, Ge. For p-type FETs, p-type impurities, such as boron, boron fluoride, indium, or the like, may be included in the p-type epitaxial structure 158. For n-type FETs, n-type impurities, such as phosphorus, arsenic, antimony, or the like, may be included in the n-type epitaxial structure 158.

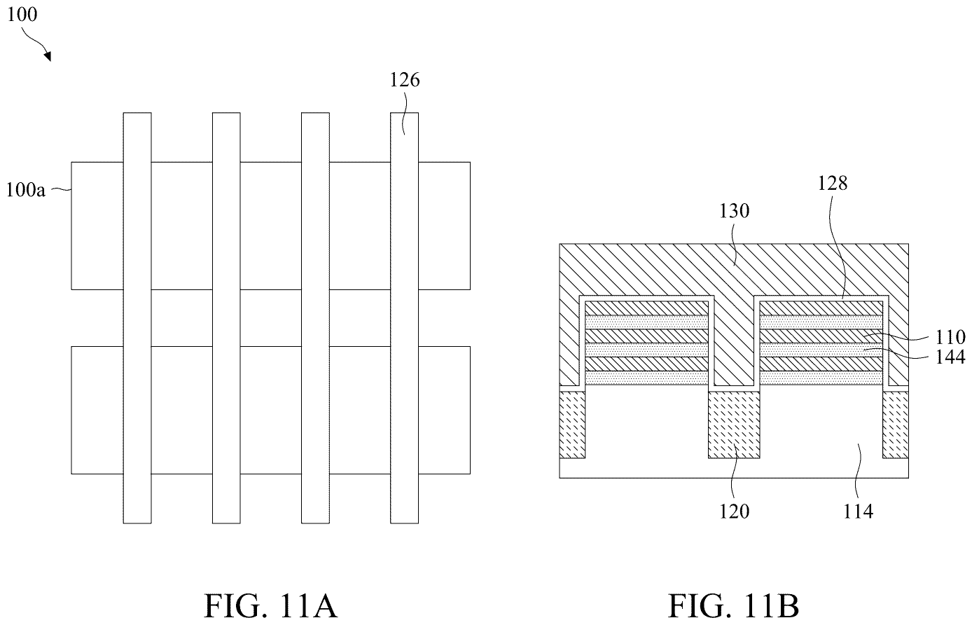

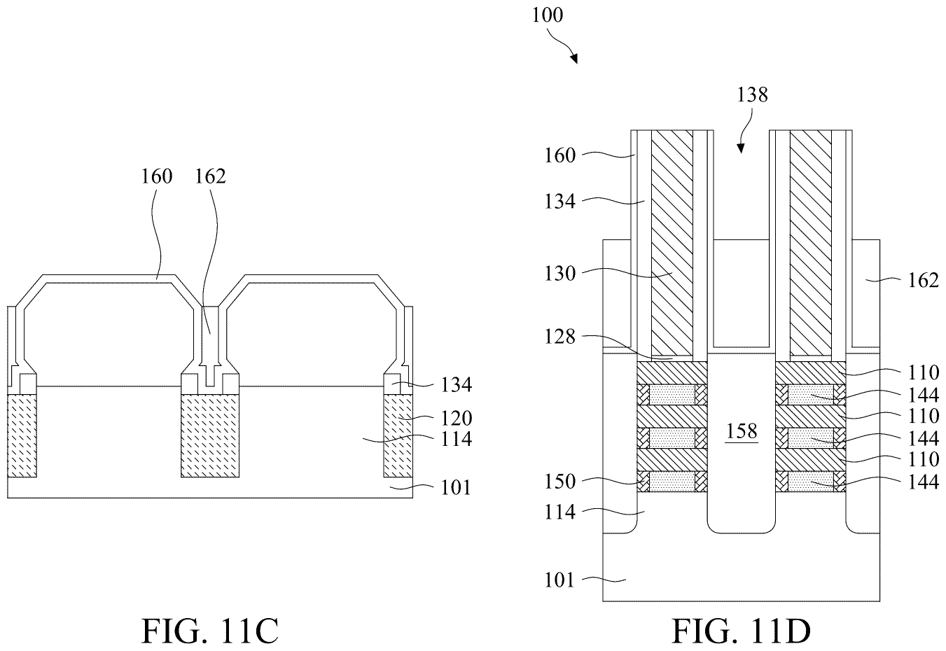

In FIGS. 11A-11D, a contact etch stop layer (CESL) 160 is conformally formed on the exposed surfaces of the semiconductor device 100, in accordance with some embodiments. The CESL 160 covers the STI regions 120, the epitaxial structures 158, and the sidewalls of the gate spacers 134. The CESL 160 may include an oxygen-containing material or a nitrogen-containing material, such as silicon nitride, silicon carbon nitride, silicon oxynitride, silicon oxycarbide, combinations thereof, or the like. The CESL 160 may be formed by CVD, PECVD, ALD, or any suitable deposition technique. Next, a first interlayer dielectric (ILD) layer 162 is formed on the CESL 160 over the semiconductor device 100. The materials for the first ILD layer 162 may include compounds including Si, O, C, and/or H, such as silicon oxide, SiOCH, SiOC, PSG, BSG, BPSG, combinations thereof, or the like. Organic materials, such as polymers, may also be used for the first ILD layer 162. The first ILD layer 162 may be deposited by FCVD, PECVD, or other suitable deposition techniques. In some embodiments, after the first ILD layer 162 is deposited, a thermal process is performed to cure the first ILD layer 162. After being cured, a recessing step, such as etch step, is performed to recess the first ILD layer 162 to below the top surface of the epitaxial structures 158. Thus, portions of the CESL 160, including portions of the CESL 160 on the upper slanted surfaces of the epitaxial structures 158, may be exposed from the first ILD layer 162.

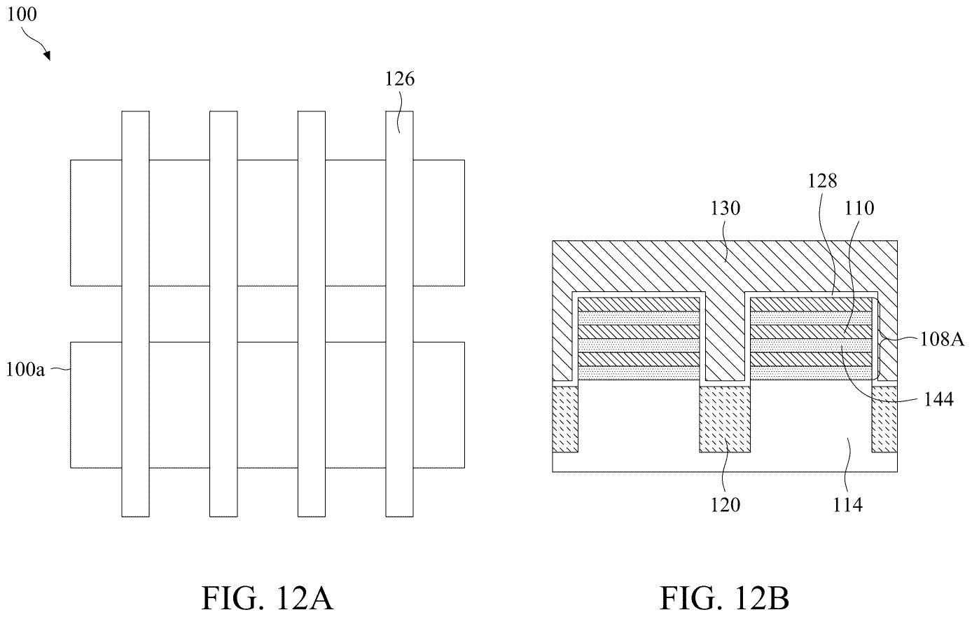

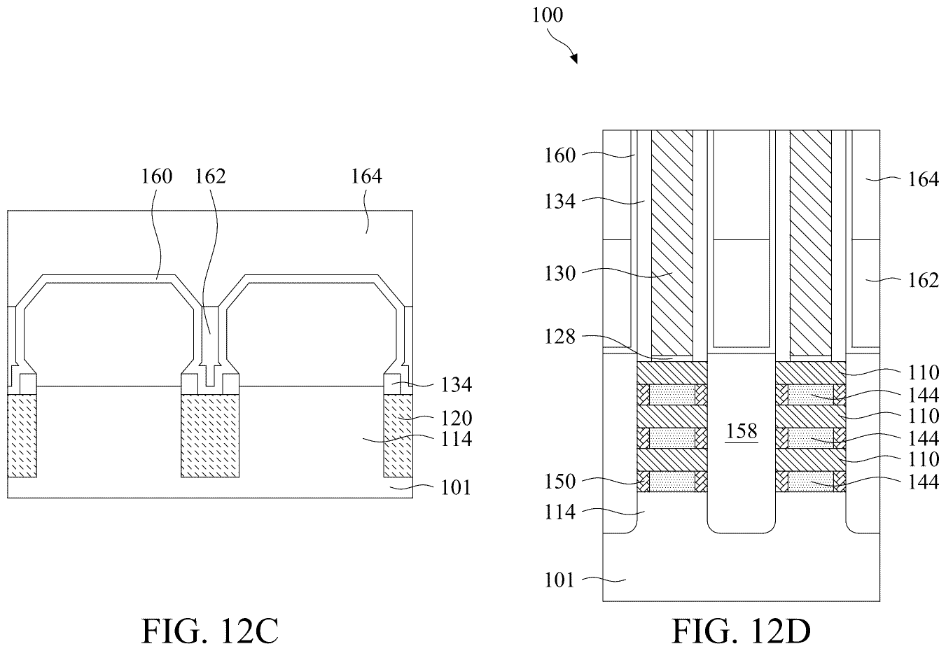

In FIGS. 12A-12D, a dielectric layer 164 is formed over and covers the first ILD layer 162 and the epitaxial structures 158, in accordance with some embodiments. The dielectric layer 164 may include silicon nitride, silicon oxynitride, or other suitable materials. The dielectric layer 164 may be formed by CVD, PECVD, LPCVD, or other suitable deposition processes. In some embodiments, a planarization process, such as CMP, may be performed to remove portions of the dielectric layer 164 until the dummy gate structures 126 are exposed.

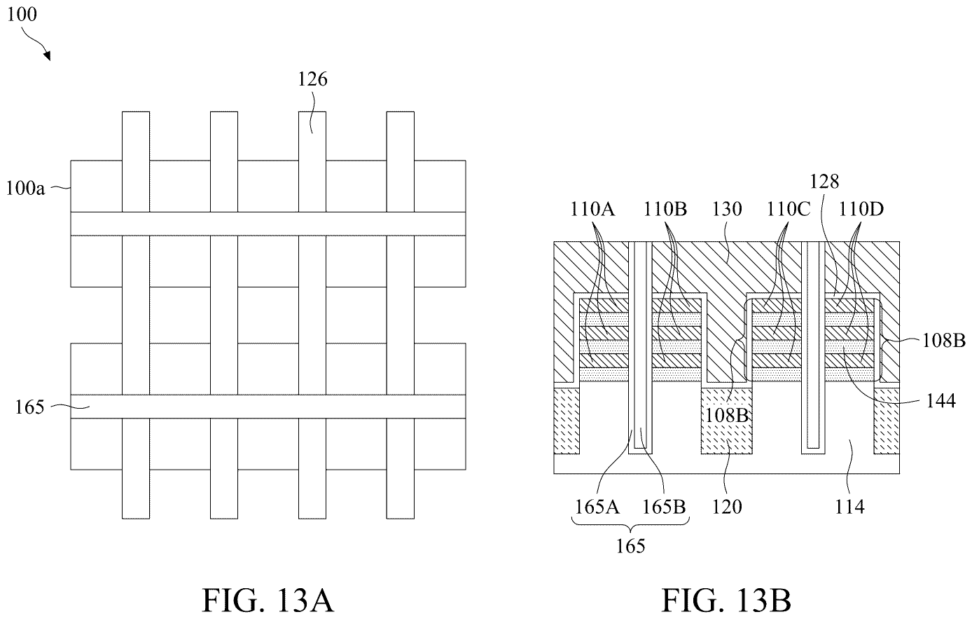

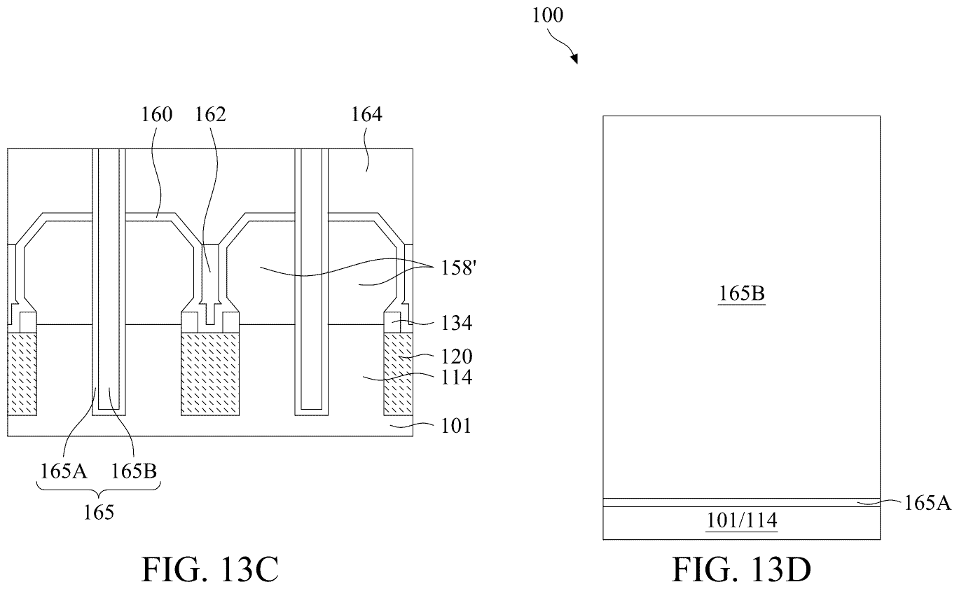

In FIGS. 13A-13D, isolation walls 165 (or also referred to as isolation structures) are formed to cut the epitaxial structures 158, the dummy gate structures 126, and the dielectric layer 164, in accordance with some embodiments. Each of the isolation wall 165 may have a longitude axis extending along a direction that is substantially perpendicular to the longitudinal axis of the dummy gate structures 126 (e.g., the X-direction in FIG. 6). For example, the isolation walls 165 may extend through dummy gate structure 126 and cut the dummy gate structures 126 to multiple sections. The isolation walls 165 may extend vertically from a top surface of the dummy gate structure 126, through first nanostructures 110 and the insulating nanostructures 144, into the fins 104/substrate 101. Accordingly, as illustrated in the FIGS. 13A-13C, one isolation wall 165 may include a plurality of first portions and a plurality of second portions alternatively arranged. Each first portion of the isolation wall 165 divides one nanostructure stack 108A (see FIG. 12B) into two separated nanostructure stacks 108B, and each second portion of the isolation wall 165 divides one epitaxial structure 158 to two separated epitaxial features 158′. In some embodiments, the outer sidewalls of the two epitaxial features 158′, including the slanted surfaces, may be substantially symmetry with respect to the isolation wall 165. For example, in an embodiment as illustrated in FIGS. 13A-13D, the first nanostructures 110 in one nanostructure stack 108A are separated to a first channel region 110A and a second channel regions 110B by one isolation wall 165, and the first nanostructures 110 in another nanostructure stack 108A are separated to a third channel region 110C and a fourth channel region 110D by another isolation wall 165. Accordingly, the distance between the first channel region 110A and the second channel region 110B and the distance between the third channel region 110C and the fourth channel region 110D are determined by the width of the isolation wall 165, which are smaller than the distance between second channel region 110B and the third channel region 110C. The isolation walls 165 may have a width of about 10 nm to about 30 nm.

In some embodiments, the formation of the isolation walls 165 includes performing an etch process to form openings corresponding to the shape of the isolation walls 165 and then depositing dielectric layers into the openings. The etch process may include an anisotropic etch process, such as RIE or NBE. Although FIGS. 13B and 13C show the isolation walls 165 have straight sidewalls, the isolation walls 165 may have curved or non-linear sidewalls. For example, the widths of the isolation walls 165 may have reduced widths toward the bottom of the isolation walls 165. Alternatively, the sidewalls of the first portions of isolation walls 165 may have a first slope respect to the vertical axis (e.g., portions adjacent to first nanostructures 110), and the sidewalls of the second portions of isolation sidewalls 165 may have a second slope different from the first slope with respect to the vertical axis (portions adjacent to the insulating nanostructures 144) because etching the material of the first to fourth channel regions 110A-110D and etching the material of the isolating nanostructures 144 may result in different etching behavior. Each of the isolation walls 165 may include a liner 165A and an isolation filler 165B. The liner 165A may include a dielectric material, such as silicon oxide, silicon oxycarbide, silicon oxynitride, a low-k dielectric, a combination thereof, or the like. The liner 165A may have a thickness of about 1 nm to about 5 nm. The isolation filler 165B may include a dielectric material such as SiN, SiON, SiC, SiCN, a combination therefore, or the like. In some embodiments, a planarization process such as CMP may be performed after the deposition of the liner 165A and the isolation filler 165B to remove excess materials of the liner 165A and the isolation filler 165B above the top surface of the dummy gate structures 126. In some embodiments, the planarization process also removes a portion of the dummy gate structure 126 and the dielectric layer 164, if needed. In an embodiment, each of the isolation walls 154 may partially or completely extend through a fin 114.

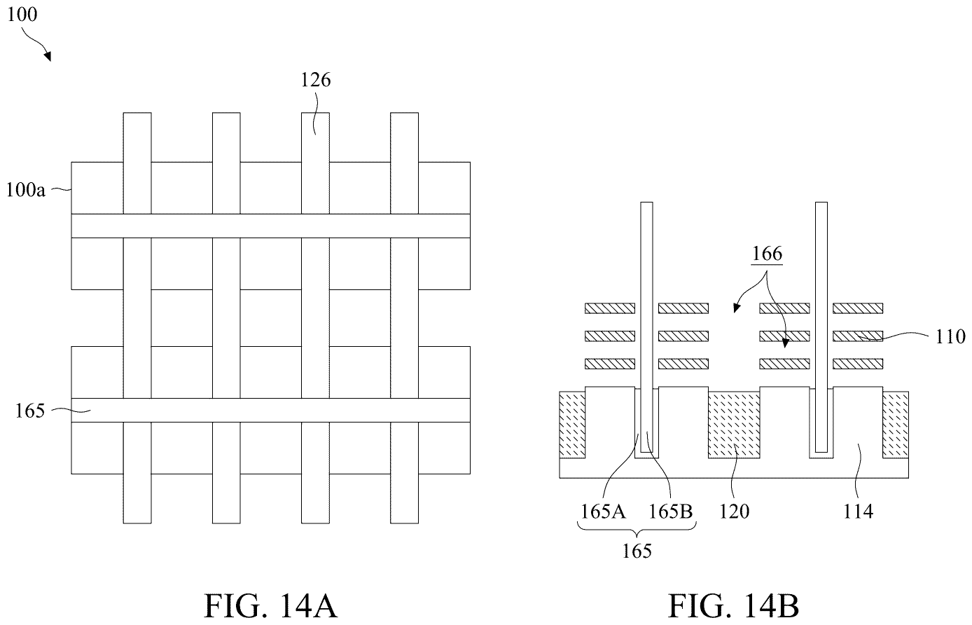

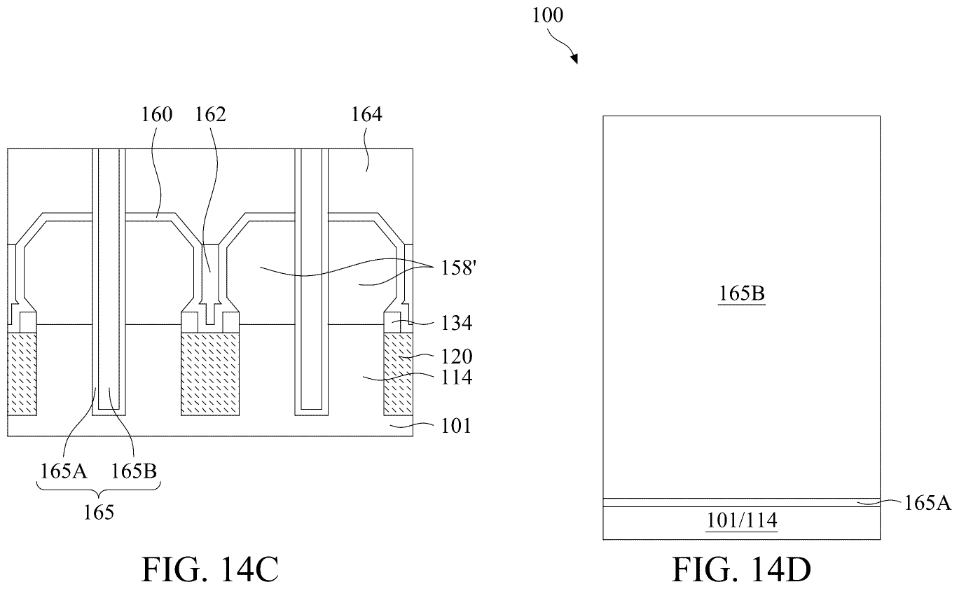

In FIGS. 14A-14C, the insulating nanostructures 144, the dummy gate electrodes 130 and the dummy gate dielectrics 128 are removed by one or more etch processes, thereby forming third openings 166, in accordance with some embodiments. In some embodiments, portions of the liners 165A of the isolation walls 165 are also removed during the etch processes. For example, as illustrated in FIG. 14B, potions of the liner 165A above the fins 114 in the third openings 166 may be removed so that the top surface of the liners 165A may be level with the top of the fins 114/substrate 101, in accordance with some embodiments. In other embodiments, the top surface of the liners 165A is lower than the top of the fins 114/substrate 101. In some embodiments, the etch processes include isotropic etch process, such as including a wet etching containing an etchants that selectively etch the insulating nanostructures 144, the dummy gate electrodes 130, the dummy gate dielectrics 128, and the isolation walls 165 at a faster rate than the first ILD layer 162 or the gate spacers 134.

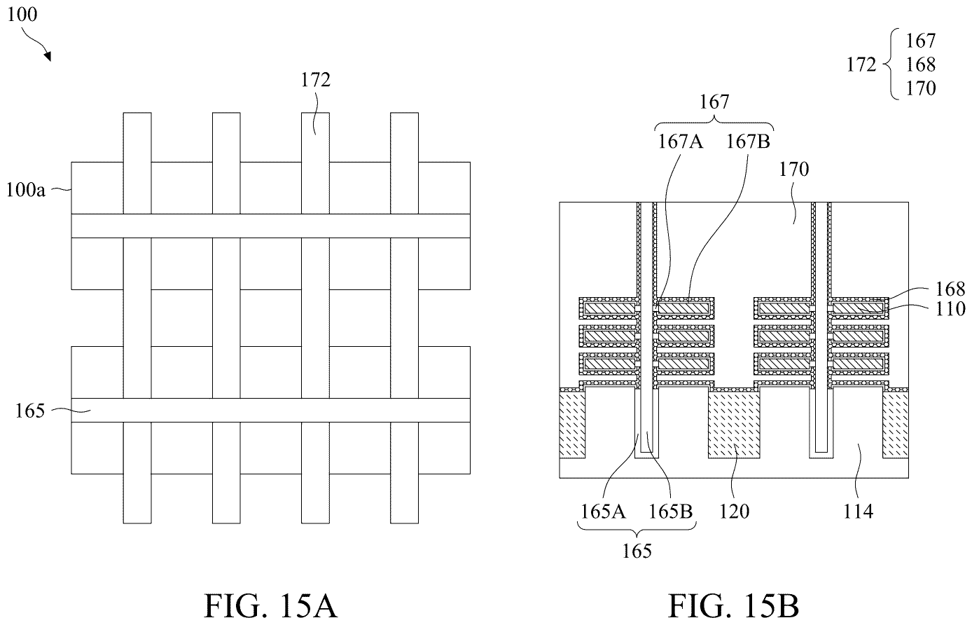

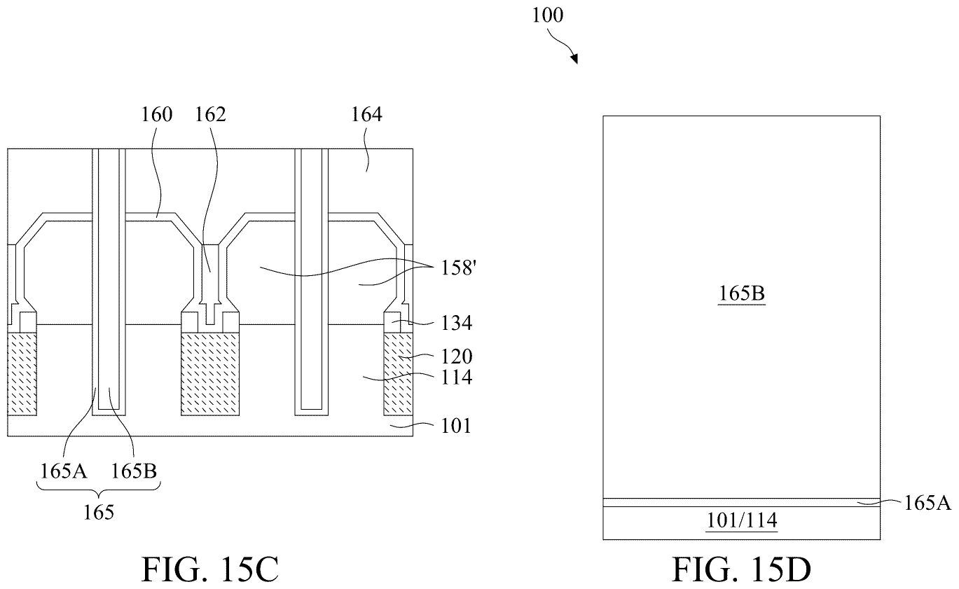

In FIGS. 15A-15C, interfacial layers 167, the gate dielectric layer 168, and the gate electrodes 170 are subsequentially formed in the third openings 169, in accordance with some embodiments. The interfacial layers 167 and gate dielectric layers 168 are conformally formed on exposed surfaces of the first nanostructures 110, the isolation walls 165, and the fins 114/substrate 101. The interfacial layer 167 may include silicon oxide, silicon oxynitride, or a combination thereof. In some embodiments, each of the first nanostructures 110 is wrapped around by the interfacial layer 167. In some embodiments, one interfacial layer 167 includes a thick portion 167A that is disposed on the inner sidewall of one first nanostructure 110 (e.g., sidewall of the first nanostructure 110 facing the isolation wall 165) and a thin portion 167B that is conformally disposed on the top surface, the bottom surface, and an outer sidewall of the adjacent first nanostructure 110 (e.g., sidewall of the first nanostructure 110 opposite to the isolation wall 156). In an embodiments, the thin portion 167B of the interfacial layer 167 also extends onto the inner sidewall of the first nanostructure 110 so the inner sidewall of the first nanostructure 110 is collectively covered by the thick portion 167A and the thin portion 167B of the interfacial layer 167. The thick portion 167A of the interfacial layer 167 may have a vertical thickness at least twice the vertical thickness of the thin portion 167B (e.g., thickness of the interfacial layer 167 on the top surface of the first nanostructure 110). In some embodiments, the thick portion 167A of the interfacial layer 167 may have a horizontal thickness (e.g., about 1 nm to about 5 nm) at least twice the horizontal thickness of the thin portion 167B of the interfacial layer 167. In some embodiments, the vertical thickness of one thick portion 167A of the interfacial layer is less than the vertical thickness the adjacent first nanostructures 110.

The gate dielectric layer 168 may be formed over the thin portion 167B of the interfacial layer 167, sidewalls of the isolation walls 165, and top surfaces and sidewalls of the fins 114/substrate 101. In an embodiment, the gate dielectric layer 168 also extends into the space between the first nanostructures 110 and the isolation walls 165 and in contact with the top surfaces and bottom surfaces of the thick portions 167A of the interfacial layers 167. Accordingly, the first nanostructures 110 are fully wrapped around by the interfacial layer 167 and partially wrapped around by the gate dielectric layer 168 in the cross-sectional view as illustrated in FIG. 15B. In an embodiment, a portion of the isolation walls 165 that is between the top and the bottom of the channel regions (e.g., 110A-110D) is covered by the interfacial layer 167 and the gate dielectric layer 168. In some embodiments, the gate dielectric layers 168 include one or more layers of a dielectric material, such as silicon oxide, silicon nitride, or high-k dielectric material (e.g., dielectric constant>10), other suitable dielectric material, and/or combinations thereof. Examples of high-k dielectric material include HfO, HfSiO, HfSiON, HfTaO, HfTiO, HfZrO, ZrO, AlO, TiO, other suitable high-k dielectric materials, and/or combinations thereof. The gate dielectric layers 168 may be formed by CVD, ALD, or any suitable deposition techniques.

The gate electrodes 170 are deposited over the gate dielectric layer 168, respectively, and fill the remaining portions of the third openings 166. The gate electrodes 170 may include a metal-containing material such as titanium nitride, titanium oxide, tantalum nitride, tantalum carbide, cobalt, ruthenium, aluminum, tungsten, combinations thereof, or multi-layers thereof. In some embodiments, the gate electrodes 170 at least includes a Ti-based material. Although single-layer gate electrodes 170 are illustrated in FIG. 15B, the gate electrodes 170 may comprise any number of liner layers, any number of work function tuning layers, and a fill material. The gate electrodes 170 may be formed by CVD, ALD, electro-plating, or other suitable deposition techniques. After filling the third openings 166, excess materials of the gate dielectric layer 168 and the gate electrodes 170 over the top surface of the dielectric layer 164 are then removed by a planarization process, such as CMP, until the top surface of the dielectric layer 164 is exposed. The remaining portions of the gate electrodes 170 and the gate dielectric layer 168 thus form replacement gate structures of the semiconductor device 100. The gate electrodes 170 and the gate dielectric layer 168 may be collectively referred to as gate structures 172. The gate structures 172 may surround channels regions (e.g., the first to fourth channel regions 110A-110D formed of the first nanostructures 110) of the semiconductor device 100.

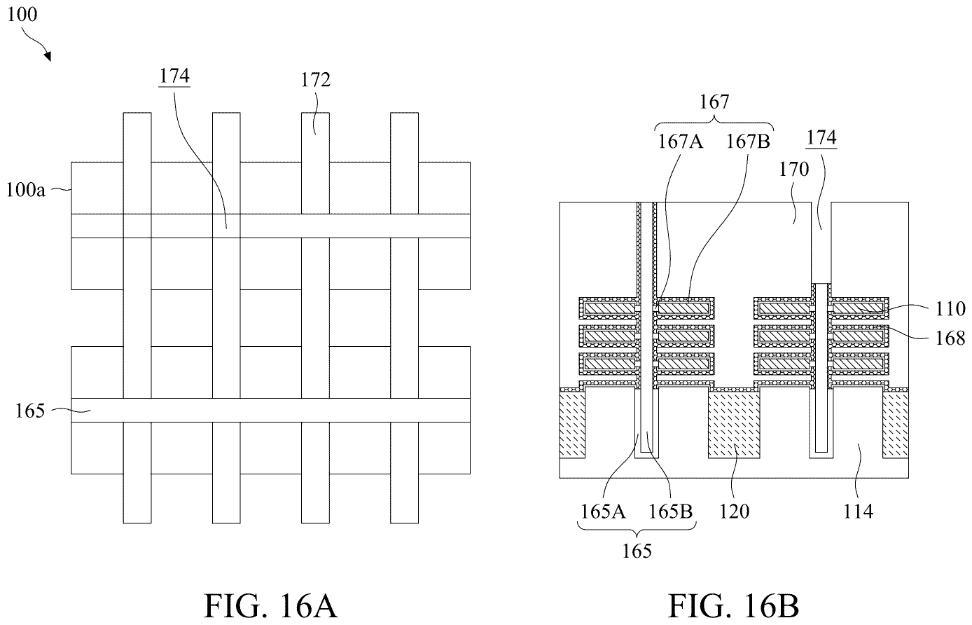

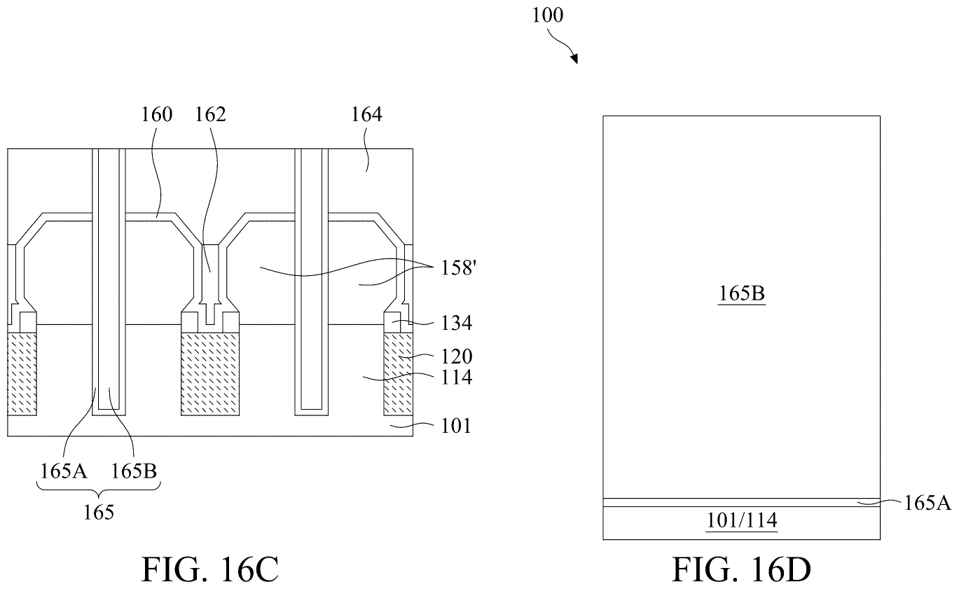

As further illustrated by FIGS. 16A-16D, openings 174 are formed by partially removing one or more of the isolation walls 165, in accordance with some embodiments. A mask that has a pattern defining the shape of the openings 174 is provided on the gate structures 172 and dielectric layer 164, and pattern may expose the one or more the isolation walls 165 that are predetermined to be partially removed. The openings 174 may extend from top surfaces of the gate electrodes 170 to a level higher than the first nanostructures 110. That is, the subsequently deposited conductive material may have a gap with the first nanostructures 110 to avoid forming short circuits with the first nanostructures 110. The mask may be removed after the openings 174 are formed. In some embodiments, the openings 174 may have a width substantially equal to or greater than the width of the isolation walls 165 in the Y-direction.

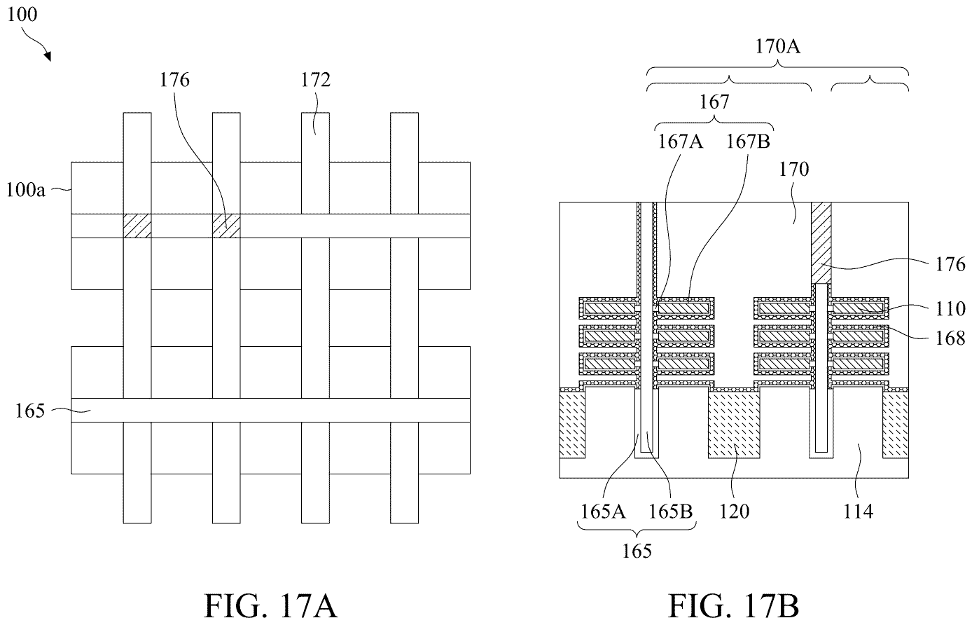

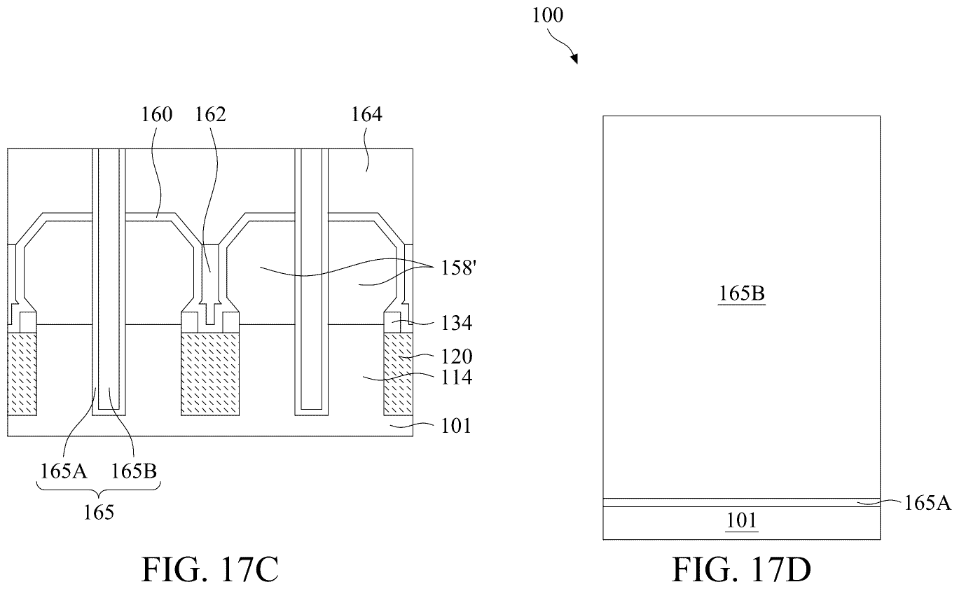

In FIGS. 17A-17D, conductive features 176 is formed in the openings 174, in accordance with some embodiments. In some embodiments, the conductive features 176 may include a same or different material from that of the gate electrodes 170. The conductive features 176 may include a conductive material such as Ru, W, Co, Cu, or other suitable metals. The formation of the conductive features 176 may include depositing one or more layer of conductive materials in the openings 174 and on the top surfaces of the gate structures 172. Thereafter, a planarization process such as CMP may be performed to remove the excess portions of the conductive material over the top surfaces of the gate structures 172. As such, conductive features 176 are formed in the openings 174 and may have top surfaces level with the gate structures 172 and the dielectric layer 164 and have bottom surfaces higher than the top surfaces of the topmost one of the first nanostructures 110 (i.e., top of channel regions). With forming the conductive features 176 in the openings 174, some sections of the gate electrodes 170 that were electrically isolated by the isolation walls 165 can be electrically connected through the conductive features 176. Accordingly, some sections of the gate electrodes 170 can be electrically connected in the level of the gate electrodes 170 without relying upper-level interconnects, thereby proving improved density and/or flexibility for routing. For example, with forming the conductive feature 176, the second channel region 110B, the third channel region 110C, and the fourth channel region 110D (see FIG. 13B) may be operated together by the sections of the gate electrodes 170 (collectively referred to as gate electrode 170A) electrically connected by the conductive features 176.

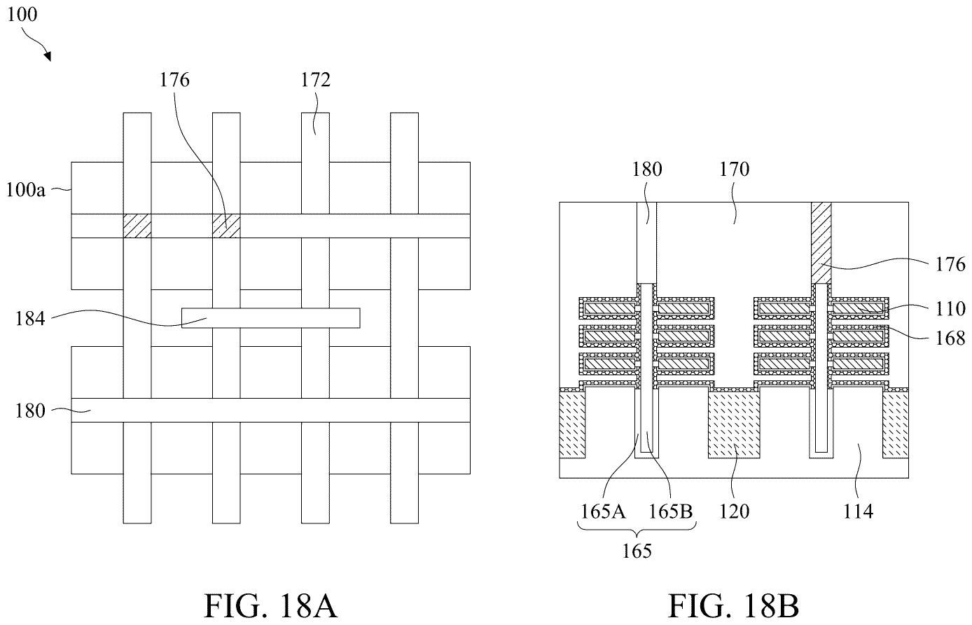

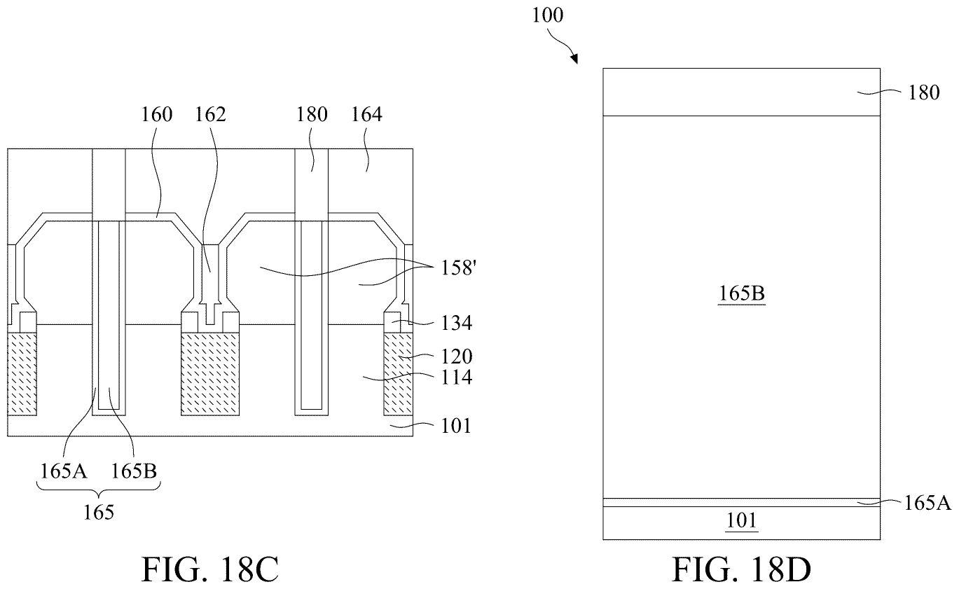

In FIGS. 18A-18D, the isolation walls 165 which are not covered by the conductive features 176 are partially removed and filling with a high-k material to form isolation helmets 180, in accordance with some embodiments. For example, the isolation helmets 180 has a longitudinal axis along the X-direction. In some embodiments, the isolation helmets 180 may extend on and cover the first portions and the second portions of the isolation walls 165. The isolation helmets 180 may include a material that has an etch selectivity to the dielectric layer 164. The isolation helmets 180 may include a high-k material (e.g., dielectric constant>10). The isolation helmets 180 may include a same material as the gate dielectric layer 168 although, in some embodiments, their materials can be different. The formation of the isolation helmets 180 may include performing an etch process (without forming mask) to remove the exposed isolation. The isolation walls 165 may be partially removed by a dry etch process such as RIE or NBE with using etch time to control the etching depth. In some embodiments, the isolation helmets 180 is predetermined to have a bottom surface higher than the top surface of the topmost first nanostructures 110 (i.e., top of a channel region) to avoid damaging the first nanostructures 110. On the other hand, the bottom surface of the isolation helmets 180 may be level with or lower than top of the epitaxial features 158′. The isolation helmets 180 may have a width equal or greater than the width of the isolation walls 165 in the Y-direction. In an example, the isolation helmets 180 has a height of about 1 nm to about 19 nm. The isolation helmets 180 may be formed by a deposition process, such as a CVD process and then be planarized to remove excess material of the isolation helmets 180 over the top surfaces of the gate electrodes 170. As such, the isolation helmets 180 may have top surfaces level with top surfaces of the gate electrodes 170.

In some embodiments, an optional cut metal gate process is performed, thereby forming isolation structures 184, in accordance with some embodiments. The cut metal gate process may include etching one or more gate structures 172 to form slots that extends along the X-direction and refill an isolation structures 184 in the slots. In some embodiments, the isolation structures 184 may include silicon nitride, silicon oxide, silicon oxynitride, or a combination thereof. For example, the isolation structures 184 may have a same or similar material as the first ILD layer 162 or the dielectric layer 164. The optional cut metal gate process and the isolation structures 184 may provide the flexibility in circuit design.

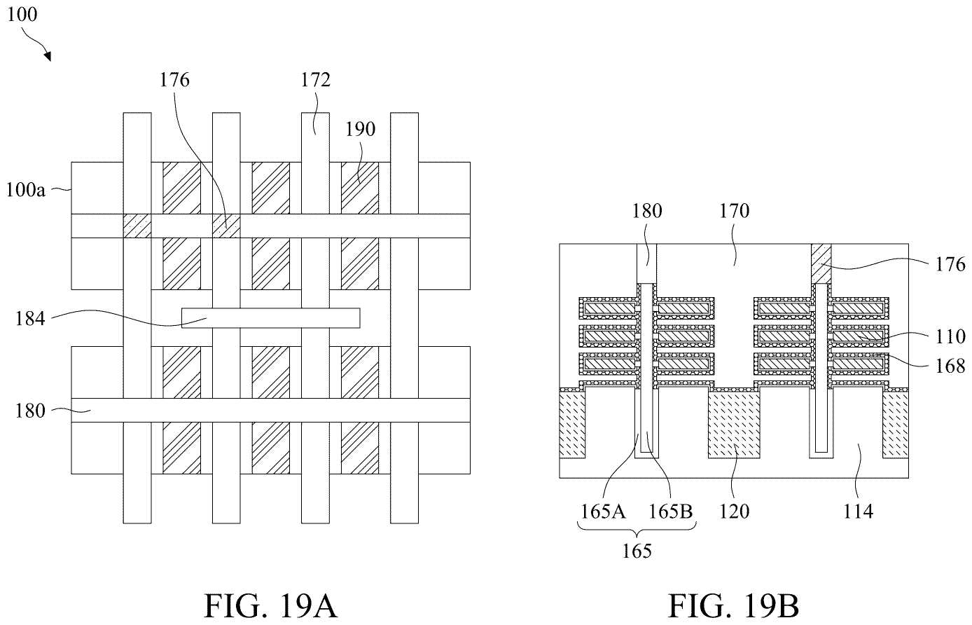

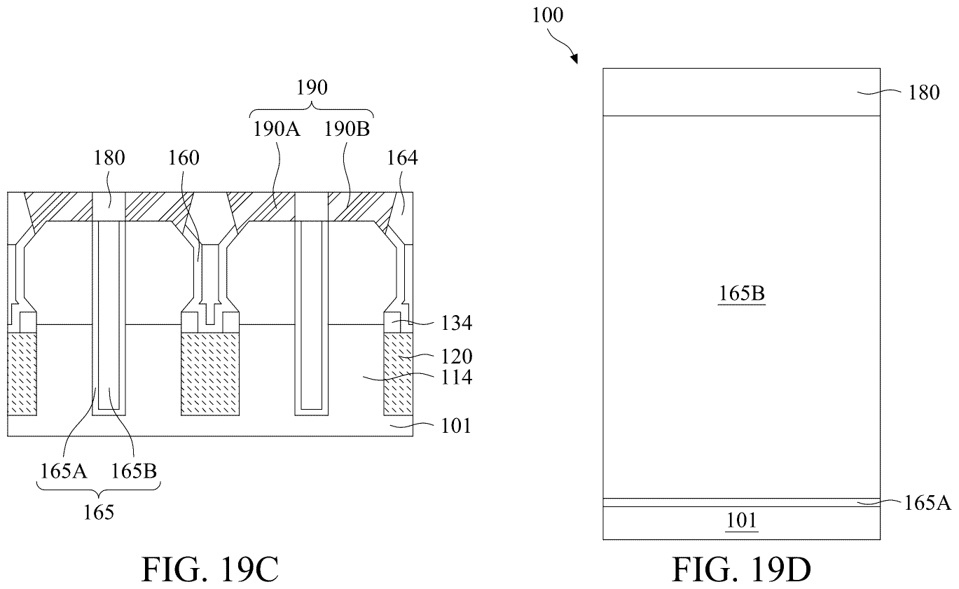

In FIGS. 19A-19D, source/drain contacts 190 are formed in the dielectric layer 164, in accordance with some embodiments. The formation of the source/drain contacts 190 may include forming openings exposing the epitaxial features by etching the dielectric layer 164 and the CESL 160; filling conductive materials into the openings; and removing the conductive materials over the dielectric layer 164 and the isolation helmets 180 by a planarizing process such as CMP. In some embodiments, the isolation helmets 180 acts masks when etching the dielectric layer 164 and the CESL 160, and the source/drain contacts 190 may be formed in a self-aligned manner. For example, the first source/drain contact 190A disposed on the one epitaxial feature 158′ and the second source/drain contact 190B disposed on another epitaxial feature 158′ may be isolated by the isolation wall 165. In some embodiments, the opening for accommodating the first source/drain contact 190A and the opening for accommodating the second source/drain contact 190B may be created by a same etch process. Thus, the slanted sidewall of the first source/drain contact 190A and slanted sidewall of the second source/drain contact 190B may be symmetric with respect to the isolation wall 165.

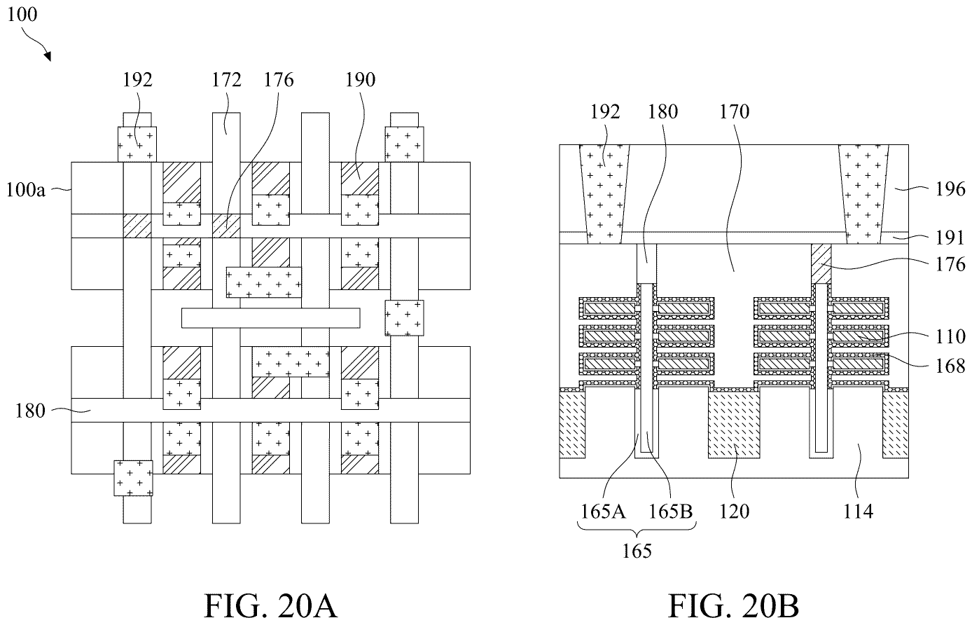

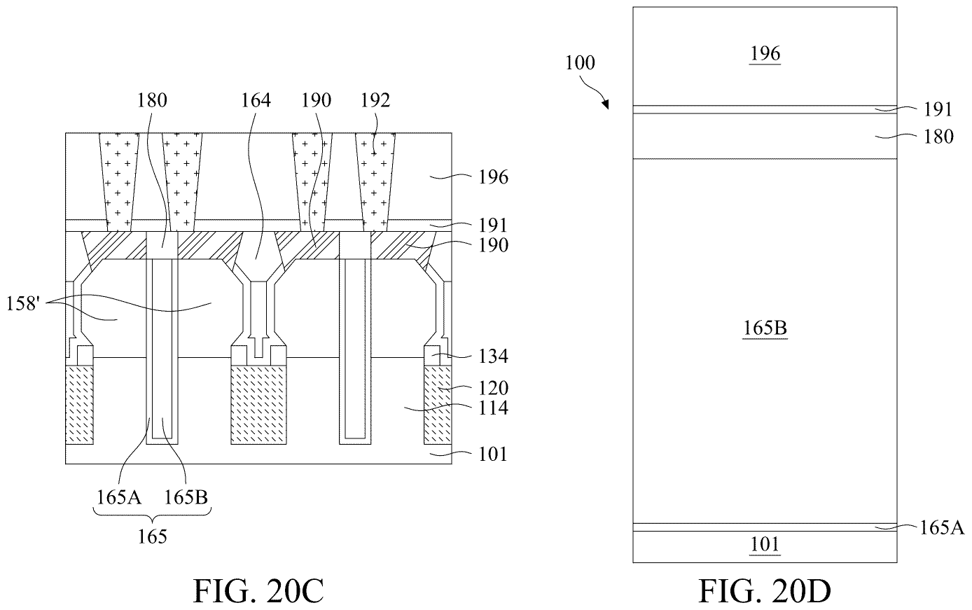

In FIGS. 20A-20C, upper-level contacts 192 and a second ILD layer 196 are formed over the source/drain contacts 190 and the dielectric layer 164, in accordance with some embodiments. The upper-level contacts 192 may be disposed on and electrically connected to corresponding source/drain contacts 190 and gate electrodes 170. In some embodiments, the upper-level contacts 192 are allowed to overlap the isolation helmets 180, thereby reducing the lithography and design requirements and increasing the process window.

Because the forming the isolation walls 165, it is allowed to grow a relatively large epitaxial structures 158 and then separate the epitaxial structures 158 epitaxial features 158′ that have a relatively small size. This approach helps prevent or reduce unwanted bridging between adjacent source/drain epitaxial features 158′, an issue that may arise when growing source/drain epitaxial features 158′ directly. Additionally, the isolation walls 165 may cut the gate structures 172 to multiple sections and provide similar functions as the isolation structures 184 formed by cut metal gate processes. The isolation walls 165 can be compatible with the cut metal gate processes and therefore provide more process and design flexibility. Furthermore, etching dummy gate structures 126 for forming the isolation walls 165 may be easier to be controlled than etching the metal gate electrodes 170. Thus, the isolation walls 165 may provide the substantially vertical sidewalls. While the sidewalls of the gate structures 172 may be self-aligned to the substantially vertical sidewalls of the isolation walls 165, the process window of separating the gate structures 172 may be increased, especially when the allowable distance between the adjacent gate structures 172 is small in advanced fabrication nodes (e.g., less than about 30 nm in the Y-direction). In some embodiments, with forming the isolation walls 165 and the isolation helmets 180 may also allow the source/drain contacts 190 to be formed on the respective epitaxial features 158′ in a self-aligned manner.

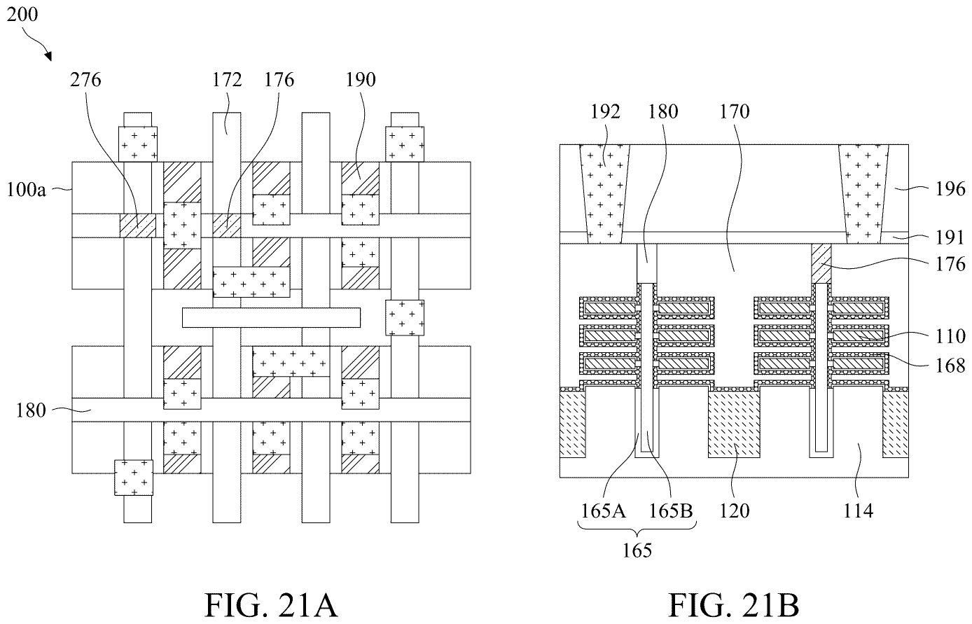

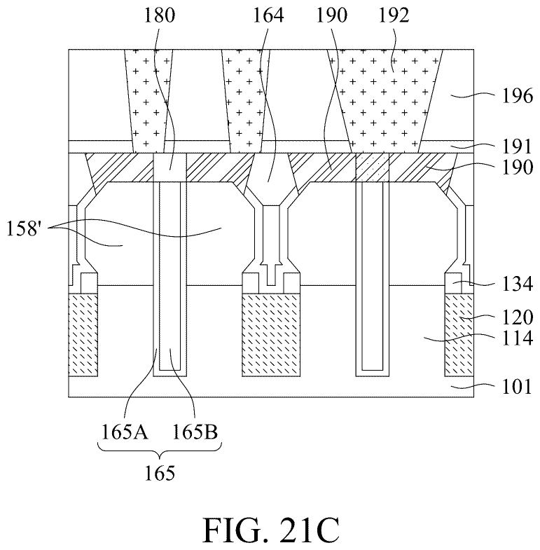

FIG. 21A-21C illustrates cross-sectional views and plan views of various stages of manufacturing a semiconductor device 200, in accordance with some embodiments. The semiconductor device 200 is similar to the semiconductor device 100, and at least one of the conductive feature 276 may be disposed in the source/drain regions when there are the needs of merging epitaxial features 158′. As a result, some of adjacent source/drain contacts 290 may be separated by the conductive features 276. The adjacent source/drain contacts 290 and the conductive features 376 may collectively from a single contact structure that is electrically connected to two adjacent epitaxial features 158′ that are isolated by the isolation wall 165.

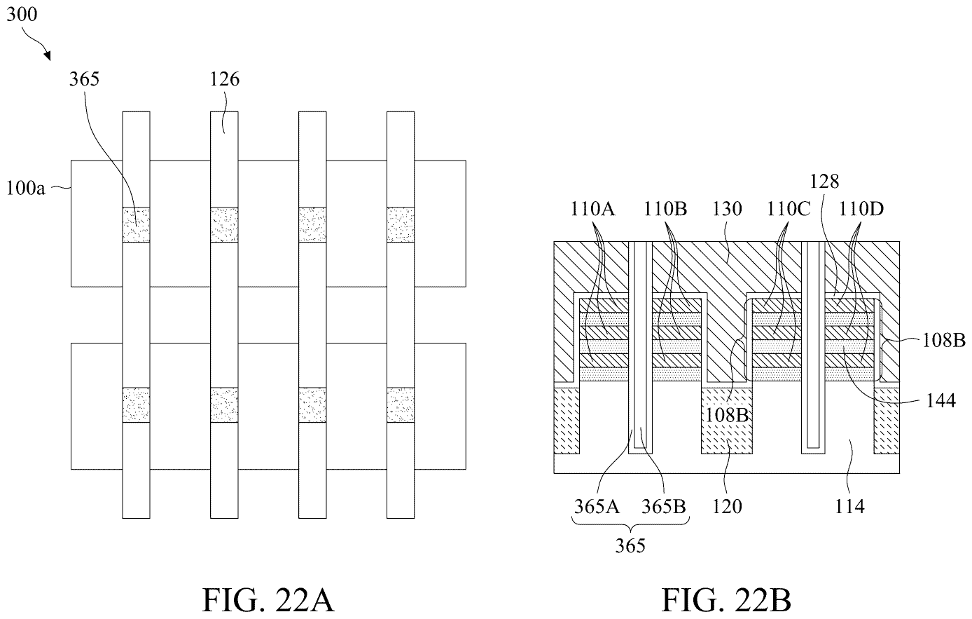

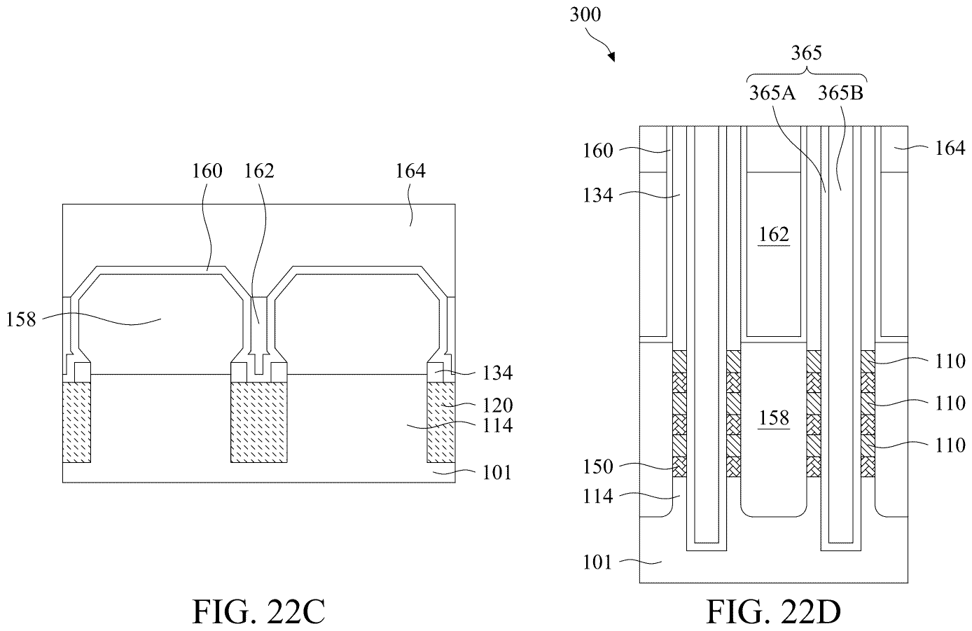

FIGS. 22A-28D illustrates cross-sectional views and plan views of various stages of manufacturing a semiconductor device 300, in accordance with some embodiments. The semiconductor device 300 is similar to the semiconductor device 100. Processing of manufacturing the semiconductor device 300 illustrated in FIGS. 22A-22D assumes the processing illustrated in FIGS. 1-12D performed prior. Accordingly, after the processing discussed above with reference to FIGS. 12A-12D, processing may proceed to FIGS. 22A-22D.

In FIGS. 22A-22D, isolation walls 365 (or also referred to as isolation structures) are formed to cut the dummy gate structures 126 and the dielectric layer 164. The isolation walls 365 are similar to the isolation walls 165, except for the lengths in the X-direction. For example, the isolation walls 365 may include same materials as the isolation walls 165 and may be formed by methods similar to those of forming the isolation walls 165. The isolation walls 365 may also include a liner 365A similar to the liner 165A and an isolation filler 365B similar to the isolation filler 165B. The isolation walls 365 may have a length in the X-direction that is same as the width of the dummy gate structures 126 or can be slightly wider than the width of the dummy gate structures 126 in the X-direction. As such, the epitaxial structures 158 are not separated by the isolation walls 365. As illustrated in the FIG. 22B, one isolation wall 365 may cut one nanostructure stack 108A to two nanostructure stacks. For example, in an embodiment as illustrated in FIGS. 22A-22D, one nanostructure stack 108A is divided into two nanostructure stacks 108B that include the first channel region 110A and the second channel region 110B separated by one isolation wall 365, and another nanostructure stack 108A is divided into two nanostructure stacks 108B that include the third channel region 110C and the fourth channel region 110D separated by another isolation wall 365.

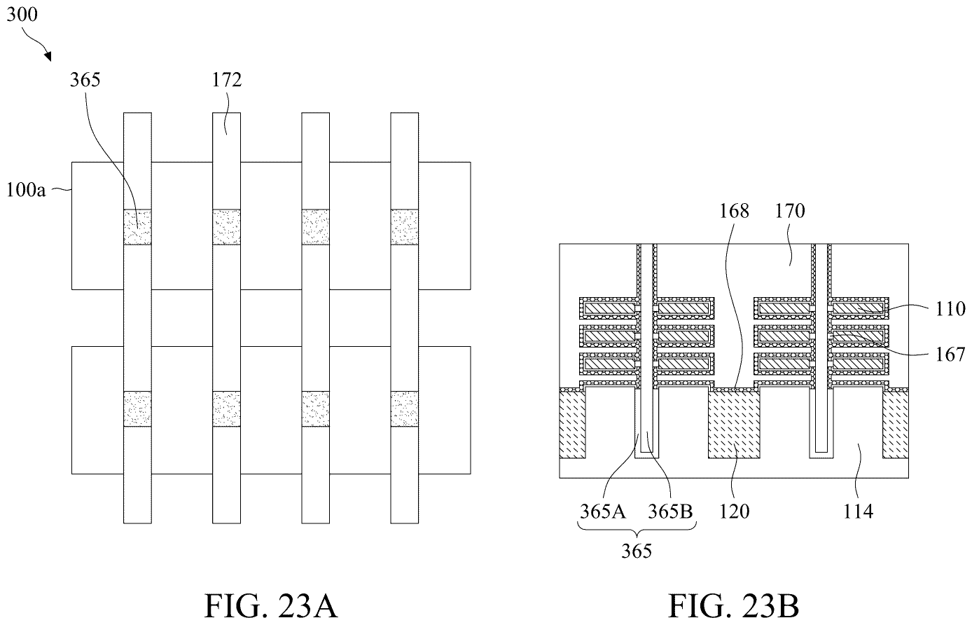

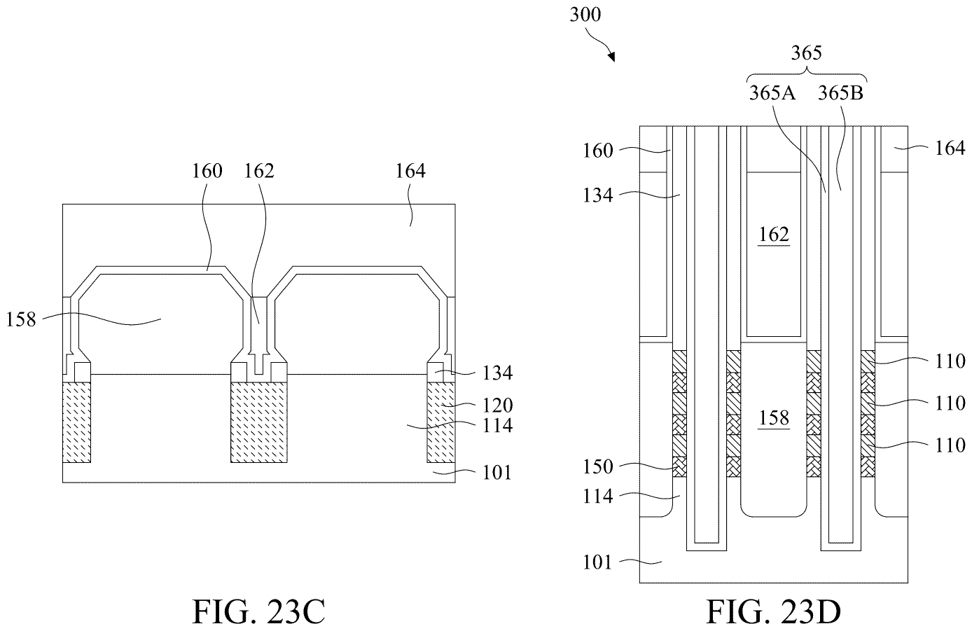

In FIGS. 23A-23D, processes similar to FIGS. 14A-15D are performed, the interfacial layers 167, the gate dielectric layer 168, and gate electrodes 170 are formed. The resulting structure as illustrated in FIGS. 23A-23D are similar to the structure as illustrated in FIGS. 15A-15D except that the isolation walls 365 does not extend to the source/drain regions so that not the epitaxial structures 158 are not cut by isolation walls.

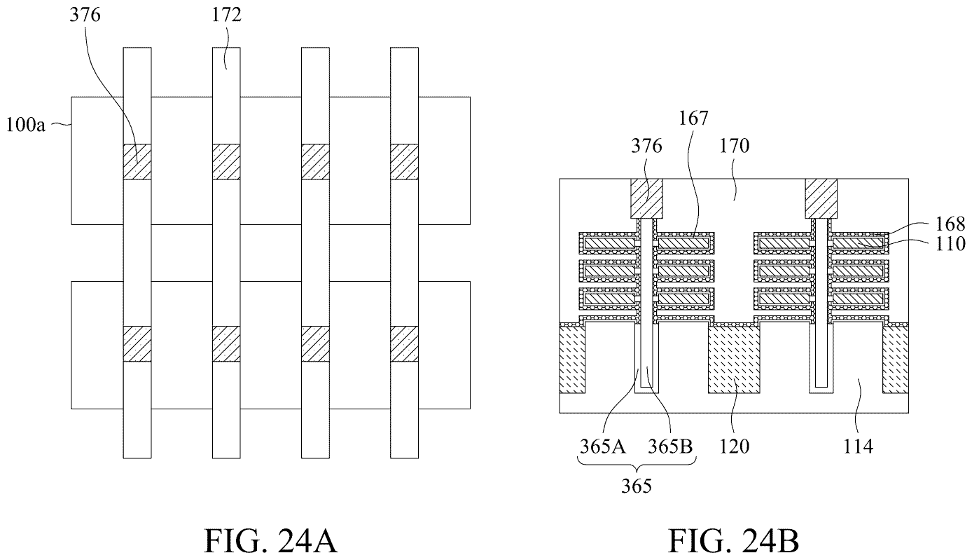

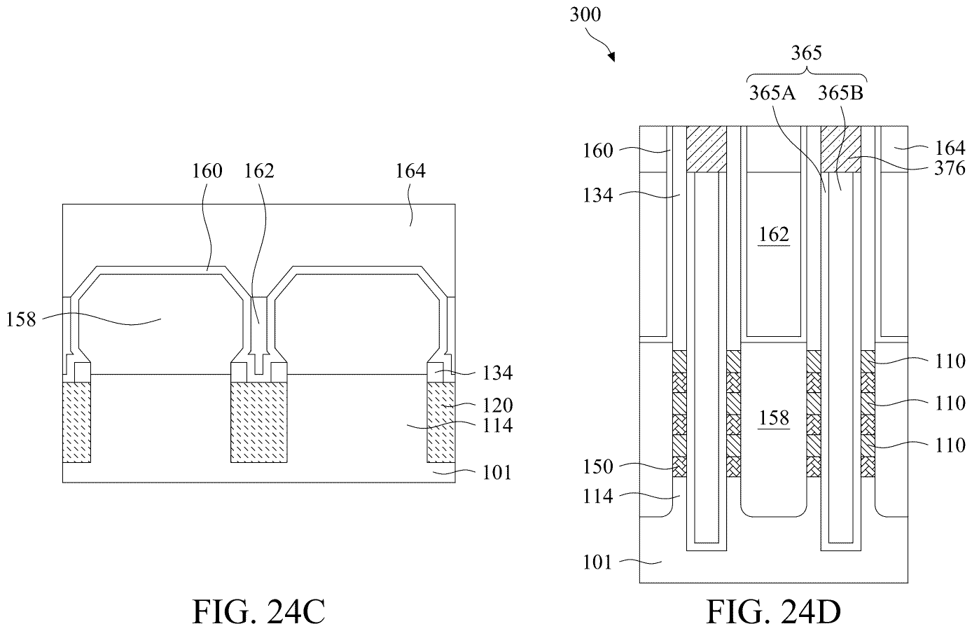

In FIGS. 24A-24D, upper portions of the isolation walls 365 are replaced with conductive features 376, in accordance with some embodiments. The formation of the conductive features 376 may include etching upper portions of the isolation walls 365 to form openings in the gate electrodes 170 and filling conductive materials in the openings to form the conductive features 376. Excess conductive materials over the gate electrodes 170 may be removed by a planarization process, such as CMP. In an embodiment, the etch processes for etching the isolation walls 365 include a dry etch such as RIE or NBE, and a mask may be provided on the gate electrodes 170 and the dielectric layer 164 before the performing the etch. In some embodiments, as illustrated in FIG. 24B, the openings have a length equal to or greater than the length of isolation wall 365 in the Y-direction (see FIG. 7A). Thus, the subsequently formed conductive features 376 may have a length equal to or greater than the length of the isolation walls 365 in the Y-direction. In an embodiment, the length of the conductive feature 376 may be about 1.2 times to about 1.8 times of the length of the isolation wall 365 in the Y-direction.

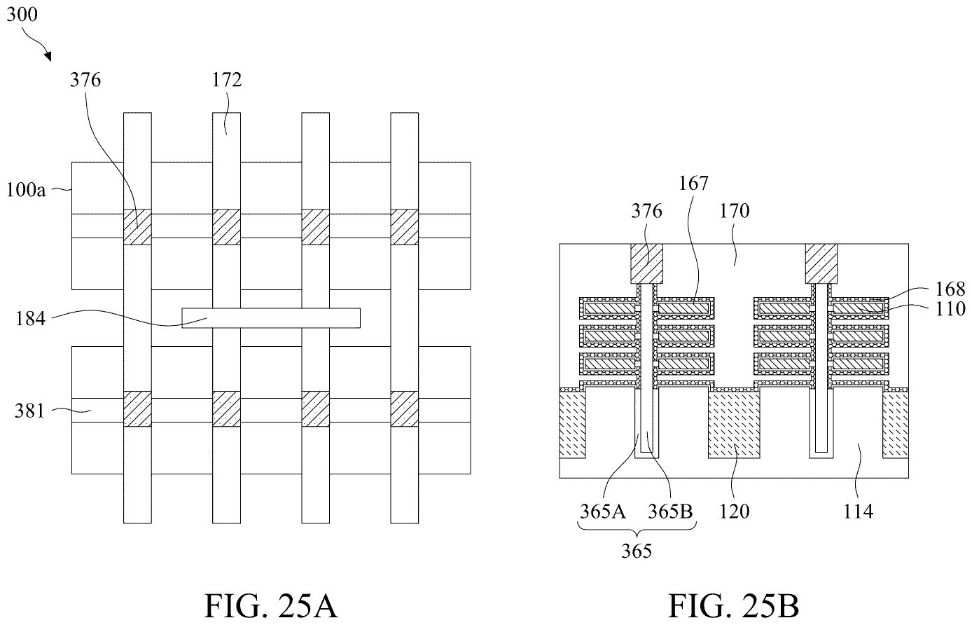

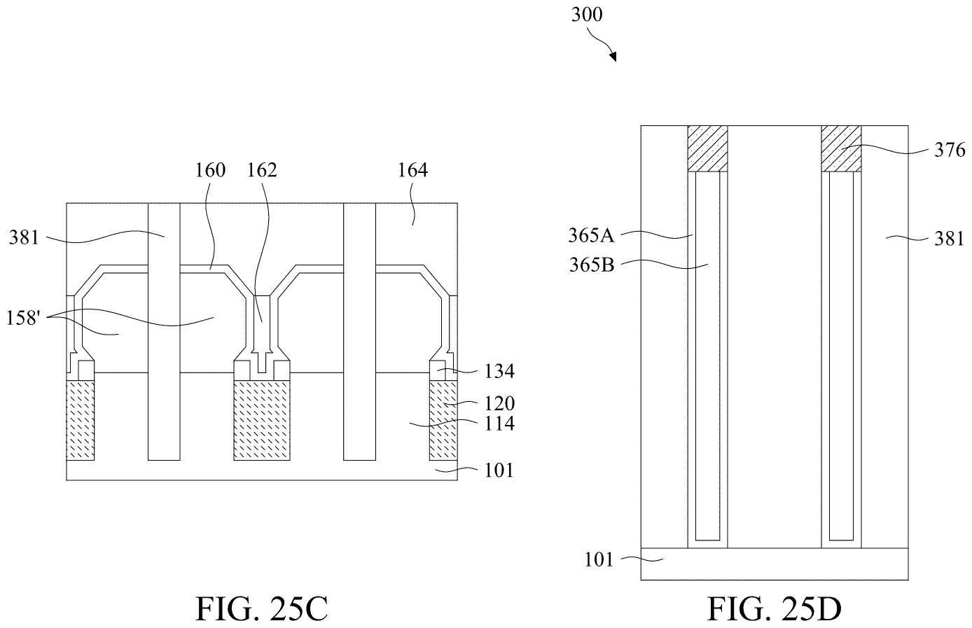

Next, in FIGS. 25A-25D, isolation walls 381 are formed, in accordance with some embodiments. The isolation walls 381 may have a longitudinal axis extending along the X-direction (see FIG. 7A). For example, the isolation walls 381 may extend through the epitaxial structures 158, such as one isolation wall 381 may separate one epitaxial structure 158 to two separated epitaxial features 158′. The isolation walls 381 may be or include a material same as the isolation filler 365B, such as SiN, SiON, SiC, SiCN, SiOCN or a combination thereof. In some embodiments the isolation walls 381 may have a bottom surface that is level with or shallower than the bottom surface of the isolation walls 365. In some embodiments, the formation of the isolation walls 381 may include one or more etch processes. The etch processes may etch the dielectric layer 164, the CESL 160, the epitaxial structures 158, and the fins 114 with providing a mask disposed on the dielectric layer 164 and the gate electrodes 170 before the etch process. The suitable insulating material is then filled in the openings created by the etch processes to form isolation walls 381. Excess of the insulating materials over the top surfaces of gate electrodes 170 and the dielectric layer 164 so that the isolation walls 381 may have top surfaces level with the top surfaces of the gate electrodes 170 and the dielectric layer 164. The isolation walls 381 and the isolation walls 365 may collectively form isolation walls similar to isolation walls 165 as illustrated in the semiconductor device 100, while the isolation walls 365 may correspond to the first portions of the isolation walls 165, and the isolation walls 381 may correspond to the second portions of the isolation walls 365. Thus, the isolation walls comprised of the isolation walls 165 and the isolation walls 381 in the semiconductor device 300 may provide functions and advantage similar to the isolation walls 165 in the semiconductor device 100. In some embodiments, an optional cut metal process may be performed to cut the metal gates, by one or more etch processes before or after the isolation walls 381 are formed. The suitable insulating material is then filled in the openings created by the etch processes to form the isolation structures 184.

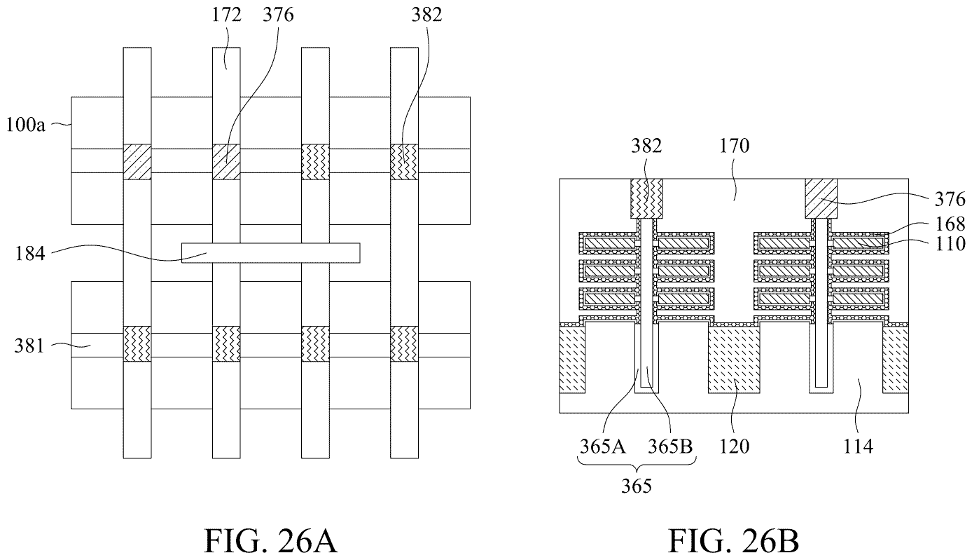

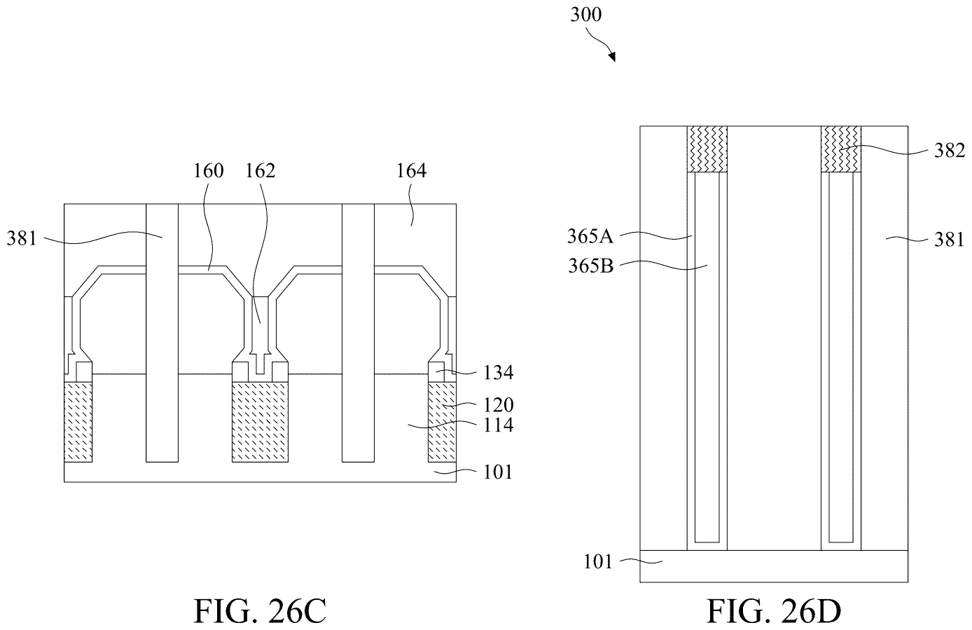

Next, in FIGS. 26A-26D, some of the conductive features 376 are replaced with the isolation helmets 382, in accordance with some embodiments. With forming the isolation helmets 382, some of the gate electrodes 170 may be electrically isolated, and their underlying channel regions may be individually controlled by those gate electrodes 170. For example, in FIG. 26B, the first channel region 110A may be individually controlled, and the second channel region 110B, third channel region 110C and fourth channel region 110D (see FIG. 13B) may be operated together by sections of the gate electrodes 170 (collectively referred to as gate electrode 370A) that are electrically connected by the conductive features 376. The conductive features 376 may include a same material as the conductive features 176 and be formed by methods similar to those for forming the conductive features 176.

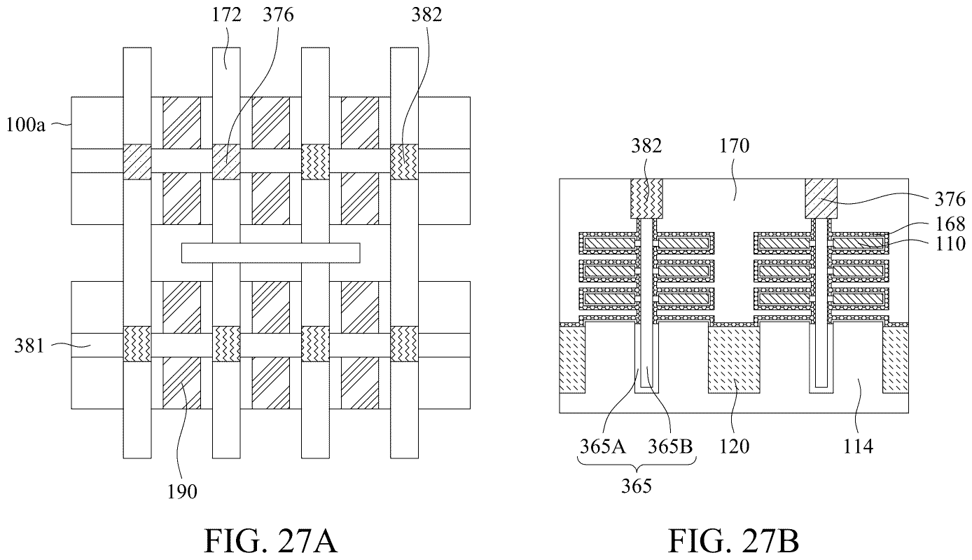

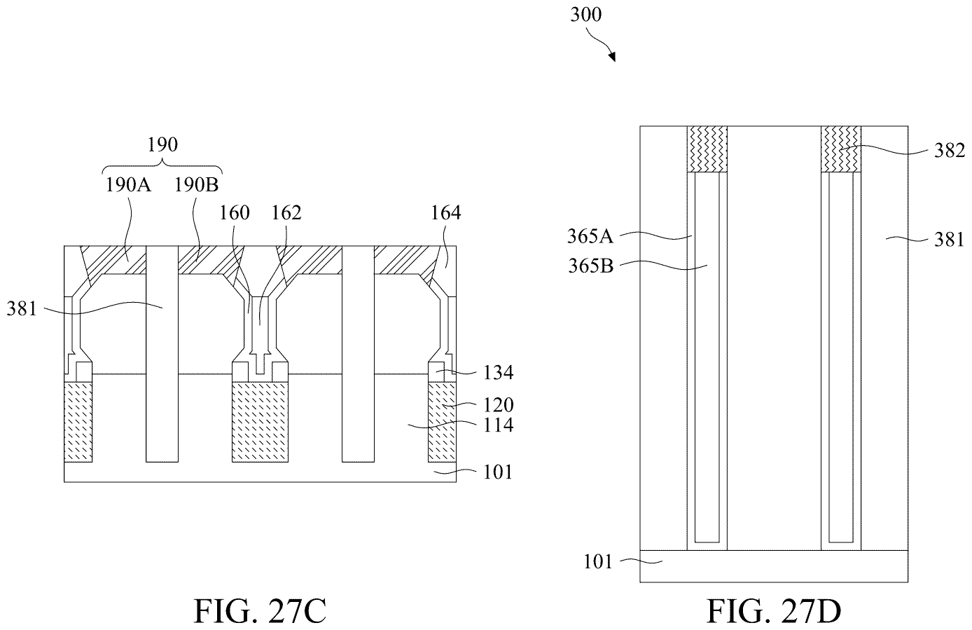

Next in FIGS. 27A-27D, source/drain contacts 190 are formed in the dielectric layer 164, in accordance with some embodiments. The formation of the source/drain contacts 190 may include forming openings exposing the epitaxial features by etching the dielectric layer 164 and the CESL 160; filling conductive materials into the openings; and removing the conductive materials over the dielectric layer 164 and the isolation walls 381 by a planarizing process such as CMP. In some embodiments, the isolation walls 381 act masks when etching the dielectric layer 164 and the CESL 160, and the source/drain contacts 190 may be formed in a self-aligned manner. For example, the first source/drain contact 190A disposed on one epitaxial feature 158′ and the second source/drain contact 190B disposed on another epitaxial feature 158′, and the first source/drain contact 190A and the second source/drain contact 190B may be isolated by the isolation wall 381. In some embodiments, the opening for accommodating the first source/drain contact 190A and the opening for accommodating the second source/drain contact 190B may be created by a same etch process. Thus, the slanted sidewall of the first source/drain contact 190A and slanted sidewall of the second source/drain contact 190B may be symmetric with respect to the isolation wall 381.

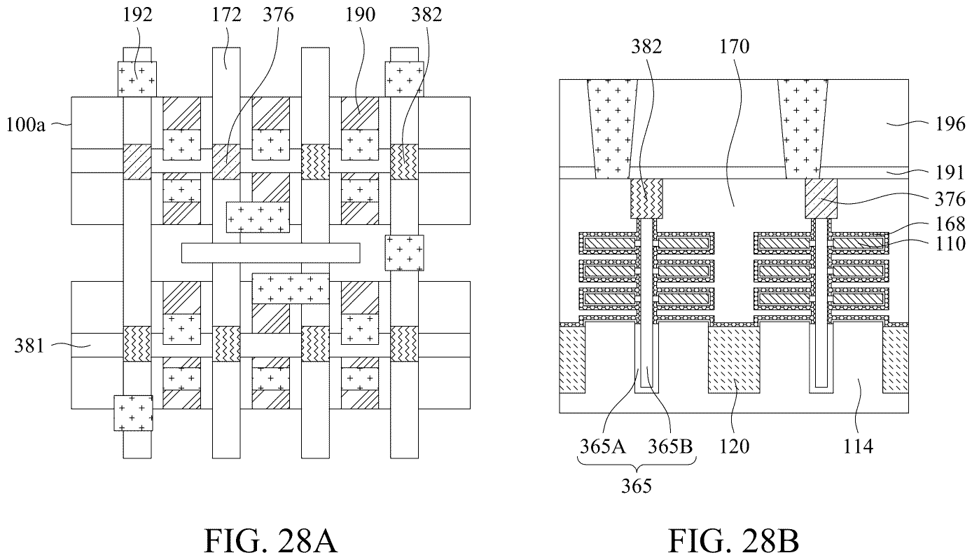

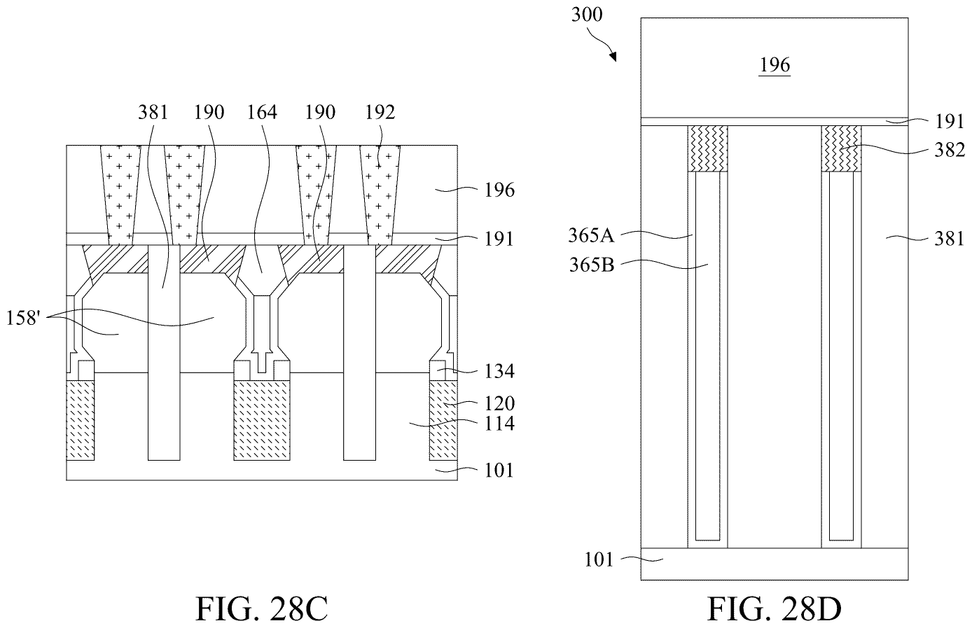

In FIGS. 28A-28C, upper-level contacts 192 and a second ILD layer 196 are formed over the source/drain contacts 190 and the dielectric layer 164, in accordance with some embodiments. The upper-level contacts 192 may be disposed on and electrically connected to corresponding source/drain contacts 190 and gate electrodes 170. In some embodiments, the upper-level contacts 192 are allowed to overlap the isolation walls 381, thereby reducing the lithography and design requirements and increasing the process window.

Because the forming the isolation walls 381, it is allowed to grow a relatively large source/drain epitaxial structures 158 and then separate the source/drain epitaxial features 158′. This approach helps prevent or reduce unwanted bridging between adjacent source/drain epitaxial features 158′, an issue that may arise when growing source/drain epitaxial features 158′ directly. Additionally, the isolation walls 365 may cut the gate structures 172 to multiple sections and provide similar functions as the isolation structures 184 formed by cut metal gate processes. The isolation walls 365 and isolation walls 381 can be compatible with the cut metal gate processes and can therefore provide more process and design flexibility. Furthermore, etching dummy gate structures 126 for forming the isolation walls 365 may be easier to be controlled than etching the metal gate electrodes 170. Thus, the isolation walls 365 may provide the substantially vertical sidewalls. While the sidewalls of the gate structures 172 may be self-aligned to the substantially vertical sidewalls of the isolation walls 365, the process window of separating the gate structures 172 may be increased, especially when the allowable distance between the adjacent gate structures 172 is small in advanced fabrication nodes (e.g., less than about 30 nm in the Y-direction). In some embodiments, forming the isolation walls 381 may also allow the source/drain contacts 190 to be formed on the respective epitaxial features 158′ in a self-aligned manner.

Embodiment of the present disclosure provide a semiconductor device and methods of manufacturing thereof. The semiconductor device includes a gate structure crossing one or more channel regions and source/drain epitaxial features interposing the channel regions. The semiconductor device also includes an isolation wall extend through the gate structure and the source/drain features. Adjacent source/drain epitaxial features may be separated by the isolation wall, and therefore the problem of unwanted bridge between adjacent epitaxial features can be resolved. In addition, the formation of the isolation walls is compatible with ordinary cut metal process and thus can provide more flexibility on the design of circuits.

An embodiment is a semiconductor device. The semiconductor device includes: a first channel region and a second channel region disposed over a semiconductor substrate; a gate structure having a longitudinal axis in a first direction and extending across the first channel region and the second channel region, wherein the gate structure includes an interfacial layer, a gate dielectric layer, and a gate electrode, wherein the gate electrode includes a Ti-based material; a first epitaxial feature and a second epitaxial feature interposing the first channel region and the gate structure in a second direction perpendicular to the first direction, wherein the first epitaxial feature include two layers containing a same semiconductor material with different concentrations; a third epitaxial feature and a fourth epitaxial feature interposing the second channel region and the gate structure in the second direction; and an isolation structure extending between the first channel region and the second channel region, wherein the isolation structure has a first sidewall facing the first channel region, wherein a portion of the first sidewall between a top of the first channel region and a bottom of the first channel region is covered by the gate dielectric layer and the interfacial layer. In an embodiment, the isolation structure extends along the second direction and between the first epitaxial feature and the second epitaxial feature and between the third epitaxial feature and the fourth epitaxial feature. In an embodiment, the semiconductor device further includes an isolating helmet disposed over the isolation structure, wherein the isolation helmet has a longitudinal axis extending along the second direction. In an embodiment, the isolation helmet at least extends through the gate electrode along the second direction. In an embodiment, the isolation helmet has a top surface level with a top surface of the gate electrode. In an embodiment, the first channel region includes a plurality of nanostructures vertically stacked, and each of the nanostructures is wrapped around by the interfacial layer. In an embodiment, each of the nanostructures is partially wrapped by the gate dielectric layer. In an embodiment, the interfacial layer has a first portion disposed on a first side of one of the nanostructures and a second portion disposed on a second side of the one of the nanostructures, wherein the second side opposites the first side and is closer to the isolation structure than the first side, wherein the first portion has a first thickness in a horizontal direction, and the second portion of the interfacial layer has a second thickness thicker than the first thickness in the horizontal direction.

Another embodiment is a semiconductor device. The semiconductor device includes a first channel region, a second channel region, a third channel region, and a fourth channel region disposed over a semiconductor substrate and subsequently arranged in a row in a first direction, wherein a distance between the first channel region and the second channel region and a distance between the third channel region and the fourth channel region are smaller than a distance between the second channel region and the third channel region; a gate structure having a longitudinal axis in the first direction and extending across the first channel region, the second channel region, the third channel region, and the fourth channel region, wherein the gate structure includes a first interfacial layer, a second interfacial layer, a gate dielectric layer, and a gate electrode, wherein the gate electrode includes a Ti-based material; a first epitaxial feature and a second epitaxial feature interposing the first channel region; a third epitaxial feature and a fourth epitaxial feature interposing the second channel region; a fifth epitaxial feature and a sixth epitaxial feature interposing the third channel region; a seventh epitaxial feature and an eighth epitaxial feature interposing the fourth channel region; a first isolation structure including a first portion extending between the first channel region and the second channel region, a second portion extending between the first epitaxial feature and the third epitaxial feature, and a third portion extending between the second epitaxial feature and the fourth epitaxial feature, wherein the second portion of the first isolation structure and the third portion of the first isolation structure interpose the first portion of the first isolation structure; a second isolation structure including a first portion of the second isolation structure extending between the third channel region and the fourth channel region, a second portion extending between the fifth epitaxial feature and the seventh epitaxial feature, and a third portion extending between the sixth epitaxial feature and the eighth epitaxial feature, wherein the second portion of the second isolation structure and the third portion of the second isolation structure interpose the first portion of the second isolation structure; a first contact disposed on and electrically coupled to the first epitaxial feature, wherein the conductivity of the first contact is greater than the conductivity of the first epitaxial feature; and a second contact disposed on and electrically coupled to the third epitaxial feature. In an embodiment, the first isolation structure has a top surface higher than a top of the first channel region and a bottom surface lower than a bottom of the first channel region. In an embodiment, a sidewall of the first isolation structure is in direct contact with the first interfacial layer and the gate dielectric layer, and a sidewall of the second isolation structure is in direct contact with the second interfacial layer and the gate dielectric layer. In an embodiment, the semiconductor device further includes an isolation helmet disposed over the first portion of the first isolation structure, the second portion of the first isolation structure, and the third portion of the first isolation structure, wherein the first contact and the second contact are separated by the isolation helmet. In an embodiment, the semiconductor device further includes a conductive helmet disposed over the first portion of the second isolation structure. In an embodiment, the semiconductor device further includes an isolation helmet disposed over the first portion of the first isolation structure and a conductive helmet disposed over the first portion of the isolation structure, wherein the isolation helmet have a top surface level with a top surface of the gate electrode, wherein the second portion of the first isolation structure and the third portion of the first isolation structure each has a top surface level with the top surface of the gate electrode. In an embodiment, the second portion of the second isolation structure and the third portion of the second isolation structure each has a top surface level with the top surface of the gate electrode.

A further embodiment is a method of fabricating a semiconductor device. The method includes: forming a plurality of nanostructures disposed over a semiconductor substrate; forming a first epitaxial structure and a second epitaxial structure interposing the nanostructures in a second direction perpendicular to the first direction, wherein the first epitaxial structure include two layers containing a same semiconductor material with different concentrations; forming an isolation structure to divide the nanostructures to first nanostructures and second nanostructures so that the first nanostructures and the second nanostructures are separated by the isolation structure in the first direction; and forming a gate structure crossing the first nanostructures and the second nanostructures; and forming a first contact over the first epitaxial feature and a second contact over the second epitaxial feature, wherein the conductivity of the first contact is greater than the conductivity of the first epitaxial structure. In an embodiment, the gate structure includes an interfacial layer, a gate dielectric layer, and a gate electrode, wherein a sidewall of the isolation structure is in direct contact with the interfacial layer and the gate dielectric layer. In an embodiment, the isolation structure divides the first epitaxial structure to a first epitaxial feature and a second epitaxial feature and divides the second epitaxial structure to a third epitaxial feature and a fourth epitaxial feature. In an embodiment, the method further includes etching an upper portion of the isolation structure to form an opening in the gate electrode and depositing an insulating material in the opening to form an isolation helmet, wherein the first contact and the second contact are separated by the isolation helmet. In an embodiment, the first epitaxial feature and the second epitaxial feature are disposed in an interlayer dielectric layer and covered by a dielectric layer, wherein the isolation helmet, the gate electrode, the first contact, the second contact, and the dielectric layer have coplanar top surfaces.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first channel region and a second channel region disposed over a semiconductor substrate;
a gate structure having a longitudinal axis in a first direction and extending across the first channel region and the second channel region, wherein the gate structure comprises an interfacial layer, a gate dielectric layer, and a gate electrode, wherein the gate electrode comprises a Ti-based material;
a first epitaxial feature and a second epitaxial feature interposing the first channel region and the gate structure in a second direction perpendicular to the first direction, wherein the first epitaxial feature comprise two layers containing a same semiconductor material with different concentrations;
a third epitaxial feature and a fourth epitaxial feature interposing the second channel region and the gate structure in the second direction; and
an isolation structure extending between the first channel region and the second channel region, wherein the isolation structure has a first sidewall facing the first channel region, wherein a portion of the first sidewall between a top of the first channel region and a bottom of the first channel region is covered by the gate dielectric layer and the interfacial layer.

2. The semiconductor device of claim 1, wherein the isolation structure extends along the second direction and between the first epitaxial feature and the second epitaxial feature and between the third epitaxial feature and the fourth epitaxial feature.

3. The semiconductor device of claim 1, further comprising an isolating helmet disposed over the isolation structure, wherein the isolation helmet has a longitudinal axis extending along the second direction.

4. The semiconductor device of claim 3, wherein the isolation helmet at least extends through the gate electrode along the second direction.

5. The semiconductor device of claim 3, wherein the isolation helmet has a top surface level with a top surface of the gate electrode.

6. The semiconductor device of claim 1, wherein the first channel region comprises a plurality of nanostructures vertically stacked, and each of the nanostructures is wrapped around by the interfacial layer.

7. The semiconductor device of claim 6, wherein each of the nanostructures is partially wrapped by the gate dielectric layer.

8. The semiconductor device of claim 7, wherein the interfacial layer has a first portion disposed on a first side of one of the nanostructures and a second portion disposed on a second side of the one of the nanostructures, wherein the second side opposites the first side and is closer to the isolation structure than the first side, wherein the first portion has a first thickness in a horizontal direction, and the second portion of the interfacial layer has a second thickness thicker than the first thickness in the horizontal direction.

9. A semiconductor device, comprising:
a first channel region, a second channel region, a third channel region, and a fourth channel region disposed over a semiconductor substrate and subsequently arranged in a row in a first direction, wherein a distance between the first channel region and the second channel region and a distance between the third channel region and the fourth channel region are smaller than a distance between the second channel region and the third channel region;
a gate structure having a longitudinal axis in the first direction and extending across the first channel region, the second channel region, the third channel region, and the fourth channel region, wherein the gate structure comprises a first interfacial layer, a second interfacial layer, a gate dielectric layer, and a gate electrode, wherein the gate electrode comprises a Ti-based material;
a first epitaxial feature and a second epitaxial feature interposing the first channel region;
a third epitaxial feature and a fourth epitaxial feature interposing the second channel region;
a fifth epitaxial feature and a sixth epitaxial feature interposing the third channel region;
a seventh epitaxial feature and an eighth epitaxial feature interposing the fourth channel region;
a first isolation structure comprising a first portion extending between the first channel region and the second channel region, a second portion extending between the first epitaxial feature and the third epitaxial feature, and a third portion extending between the second epitaxial feature and the fourth epitaxial feature, wherein the second portion of the first isolation structure and the third portion of the first isolation structure interpose the first portion of the first isolation structure;
a second isolation structure comprising a first portion of the second isolation structure extending between the third channel region and the fourth channel region, a second portion extending between the fifth epitaxial feature and the seventh epitaxial feature, and a third portion extending between the sixth epitaxial feature and the eighth epitaxial feature, wherein the second portion of the second isolation structure and the third portion of the second isolation structure interpose the first portion of the second isolation structure;
a first contact disposed on and electrically coupled to the first epitaxial feature, wherein the conductivity of the first contact is greater than the conductivity of the first epitaxial feature; and
a second contact disposed on and electrically coupled to the third epitaxial feature.

10. The semiconductor device of claim 9, wherein the first isolation structure has a top surface higher than a top of the first channel region and a bottom surface lower than a bottom of the first channel region.

11. The semiconductor device of claim 9, wherein a sidewall of the first isolation structure in direct contact with the first interfacial layer and the gate dielectric layer, and a sidewall of the second isolation structure is in direct contact with the second interfacial layer and the gate dielectric layer.

12. The semiconductor device of claim 9, further comprising an isolation helmet disposed over the first portion of the first isolation structure, the second portion of the first isolation structure and the third portion of the first isolation structure, wherein the first contact and the second contact are separated by the isolation helmet.

13. The semiconductor device of claim 12, further comprising a conductive helmet disposed over the first portion of the second isolation structure.

14. The semiconductor device of claim 10, further comprising an isolation helmet disposed over the first portion of the first isolation structure and a conductive helmet disposed over the first portion of the isolation structure, wherein the isolation helmet have a top surface level with a top surface of the gate electrode, wherein the second portion of the first isolation structure and the third portion of the first isolation structure each has a top surface level with the top surface of the gate electrode.

15. The semiconductor device of claim 14, wherein the second portion of the second isolation structure and the third portion of the second isolation structure each has a top surface level with the top surface of the gate electrode.

16. A method of fabricating a semiconductor device, the method comprising:
forming a plurality of nanostructures disposed over a semiconductor substrate;
forming a first epitaxial structure and a second epitaxial structure interposing the nanostructures in a second direction perpendicular to the first direction, wherein the first epitaxial structure comprise two layers containing a same semiconductor material with different concentrations;
forming an isolation structure to divide the nanostructures to first nanostructures and second nanostructures so that the first nanostructures and the second nanostructures are separated by the isolation structure in the first direction; and
forming a gate structure crossing the first nanostructures and the second nanostructures; and
forming a first contact over the first epitaxial feature and a second contact over the second epitaxial feature, wherein the conductivity of the first contact is greater than the conductivity of the first epitaxial structure.

17. The method of claim 16, wherein the gate structure comprises an interfacial layer, a gate dielectric layer, and a gate electrode, wherein a sidewall of the isolation structure is in direct contact with the interfacial layer and the gate dielectric layer.

18. The method of claim 17, wherein the isolation structure divides the first epitaxial structure to a first epitaxial feature and a second epitaxial feature and divides the second epitaxial structure to a third epitaxial feature and a fourth epitaxial feature.

19. The method of claim 18, further comprising etching an upper portion of the isolation structure to form an opening in the gate electrode and depositing an insulating material in the opening to form an isolation helmet, wherein the first contact and the second contact are separated by the isolation helmet.

20. The method of claim 19, wherein the first epitaxial feature and the second epitaxial feature are disposed in an interlayer dielectric layer and covered by a dielectric layer, wherein the isolation helmet, the gate electrode, the first contact, the second contact, and the dielectric layer have coplanar top surfaces.
